(19) United States
(12) Patent Application Publication
(10) Pub. No.: US 2026/0308432 A1
(43) Pub. Date: Oct. 8, 2026

(54) SEMICONDUCTOR PACKAGE MANUFACTURING METHODS USING HYBRID DIE BONDING WITH SPIN-ON SILOXANE MATERIALS

(71) Applicant: Solstice Advanced Materials US, Inc., Morris Plains, NJ (US)

(72) Inventors: Desaraju Varaprasad, Dublin, CA (US); Mark O'Neill, Charlotte, NC (US); Venky Sundaram, Charlotte, NC (US); Awdhoot Kerkar, Rockaway, NJ (US); Hongmin Huang, Cupertino, CA (US); Krishna Balantrapu, Princeton, NJ (US); Zeyu Wu, Charlotte, NC (US); Amanuel H. Gebrebrhan, San Jose, CA (US); Tiffany Nguyen, San Jose, CA (US)

(21) Appl. No.: 19/637,893

(22) Filed: Apr. 2, 2026

Related U.S. Application Data
(60) Provisional application No. 63/783,484, filed on Apr. 4, 2025.

(51) Int. Cl. C09J 183/04; C08G 77/04; H10W 72/30; H10W 80/00; H10W 90/00

(52) U.S. Cl. CPC C09J 183/04; C08G 77/04; C08G 77/045; H10W 72/354; H10W 80/327; H10W 90/792

(57) ABSTRACT

A semiconductor package including a first semiconductor component and a second semiconductor component is provided. The first semiconductor component and second semiconductor component are bonded together with a bonding layer. The bonding layer may comprise a siloxane coating, and optionally a SiO₂ coating. Further, a method of fusing the first semiconductor component and the second semiconductor component forming a device is provided. The method includes applying a siloxane coating composition to the first semiconductor component, applying either a siloxane coating composition or a SiO₂ coating composition to the second semiconductor component, contacting the first semiconductor component and the second semiconductor component together to form a device, and curing the device.

### CROSS-REFERENCE TO RELATED APPLICATION

This application claims the benefit of U.S. Provisional Application No. 63/783,484, filed Apr. 4, 2025, which is incorporated herein by reference in its entirety for all purposes.

### FIELD

The present disclosure relates generally to the use of spin-on siloxane materials to achieve hybrid die bonding in three dimensional electronic components, such as semiconductor die packages.

### BACKGROUND

Conventional two-dimensional (2D) geometrical scaling of conventional transistors continues to be challenged by device architecture evolutions enabled by advancements in material science and process engineering. Three-dimensional integrated circuits (3D-IC) represent a radical departure from traditional 2D IC and 2D package integration by vertical stacking of dies, wafers, or dies on wafers, to provide extremely dense interconnects. 3D ICs have been recognized as a next generation semiconductor technology, which has the advantage of high performance, low power consumption, small physical size and high integration density. 3D ICs provide a path to continue to meet the performance/cost demands of next generation devices while remaining at more relaxed gate lengths with less process complexity.

Semiconductor packages typically include a semiconductor die (e.g., memory chip, microprocessor chip, imager chip) mounted on a substrate or a semiconductor wafer and encased in a protective covering (e.g., an encapsulating material). The semiconductor die may include functional features, such as memory cells, processor circuits, or imager devices, as well as bond pads electrically connected to the functional features. The process of attaching different semiconductor dies to each other, so called three-dimensional integration, can employ multiple process technologies which are being developed to enable intimate integration of the different semiconductor die, such as wafer-on-wafer (WoW), chip-on-wafer (CoW), and chip-on-chip (CoC). These devices can improve functional performance, reduce power consumption, and improve cost and reliability. Individual semiconductor dies can further be stacked in the semiconductor assemblies. Hybrid bonding, also referred to as fusion bonding or direct bonding, describes a bonding process with minimal intermediate layers between semiconductor dies and/or the semiconductor wafer. The hybrid bonding technique helps semiconductor die manufacturers meet demands for a reduction in the volume occupied by semiconductor die assemblies. Gap fill dielectric materials are used to fill spaces between components, interconnects, or layers and play a critical role in ensuring structural integrity, electrical isolation, and thermal management. Redistribution layers in advanced packages and interposers are another key technology enabling heterogenous integration.

Current hybrid bonding processes are based on silicon oxide dielectric bonding layers that are deposited typically using plasma enhanced chemical vapor deposition (PECVD) methods. Exemplary process flows can be found, for example, from presentations by Applied Materials and Technology at IEDM 2024. To prepare for the Hybrid Bonding (HB) process for 3D ICs, a number of process steps akin to damascene interconnect process technology must be utilized, including: deposition of a first dielectric layer and a second bonding layer; reactive ion etch (RIE) processing; conductive diffusion barrier and copper seed; electrochemical deposition (ECD) for filling of the trenches and vias with copper; and chemical mechanical polishing (CMP) to create a nanoscale smooth surface. To ensure a strong bond between the devices, the surfaces are subjected to high vacuum plasma activation step to enable low pressure dielectric-to-dielectric bonding. First a thermal bonding step ensures sufficient bonding through dielectric-to-dielectric chemical bonds, followed by a high temperature annealing step to complete copper interdiffusion to form a metallurgical bond for interconnects.

Gap fill dielectric materials are indispensable in heterogeneous integration (HI), acting as a multifunctional layer that ensures electrical performance, mechanical stability, and thermal management while enabling the complexity and miniaturization of modern semiconductor systems. In HI, uneven surfaces or gaps arise from stacking dies or bonding dissimilar materials. Gap fill dielectrics fill voids, trenches, or spaces between components (e.g., between stacked dies, interconnects, or chiplets), providing mechanical stability and a planar surface for subsequent processing steps.

Redistribution layers (RDLs) are interconnect layers typically made through conventional damascene integration and used to “redistribute” or reroute electrical connections from the die's original input/output (I/O) pads to new locations, such as in adjacent or stacked dies. RDLs play a critical role in enabling connectivity, scalability, and packaging flexibility for HI systems.

Therefore, there are a number of applications in advanced packaging technology in need of new dielectric materials with tailorable properties such as dielectric constant, modulus, stress, and coefficient of thermal expansion (CTE) that would benefit integration across many unit operations of advanced packaging processes and systems.

### SUMMARY

The present disclosure provides a semiconductor package including a first semiconductor component and a second semiconductor component. The first semiconductor component is coated with a siloxane coating. The second semiconductor component may be coated in either the siloxane coating or a SiO₂ coating. Further a method of fusing the first semiconductor component and the second semiconductor component forming a device is provided. The method includes applying a siloxane coating composition to the first semiconductor component, applying either a siloxane coating composition or a SiO₂ coating composition to the second semiconductor component, contacting the first semiconductor component and the second semiconductor component together to form the device, and curing the device.

The present disclosure provides a semiconductor package. The semiconductor package includes a first semiconductor component and a second semiconductor component bonded together with a bonding layer. The bonding layer includes a siloxane coating composition of the following formula:

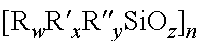

wherein R, R′, and R″ are each an alkyl group, an aryl group, a hydroxyl group, or an alkoxyl group; w is 0-1.5; x is 0-1.5; y is 0-1.5; z is 1.2-2; and n is 10-100,000. Any of R, R′, or R″ may also contain a reactive functional group, wherein the alkyl group and/or the aryl group may each independently include one or more polar protic or aprotic functional groups selected from, but not limited to, hydroxyl, amino, or carboxyl functionalities.

The present disclosure further provides a second embodiment of a semiconductor package. The semiconductor package includes a first semiconductor component and a second semiconductor component bonded together with a bonding layer. The bonding layer includes first coating composition comprising a siloxane coating; and a second coating. The siloxane coating is of the following formula:

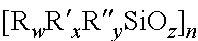

wherein R, R′, and R″ are each an alkyl group, an aryl group, a hydroxyl group, or an alkoxyl group; w is 0-1.5; x is 0-1.5; y is 0-1.5; z is 1.2-2; and n is 10-100,000. Any of R, R′, or R″ may also contain a reactive functional group, wherein the alkyl group and/or the aryl group may each independently include one or more polar protic or aprotic functional groups selected from, but not limited to, hydroxyl, amino, or carboxyl functionalities.

The present disclosure provides a method of fusing a first semiconductor component and a second semiconductor component to form a device. The method includes: applying a first coating composition to a top surface of the first semiconductor component to form a first coated semiconductor component; applying a second coating composition to a top surface of the second semiconductor component to form a second coated semiconductor component; contacting the top surface of the first coated semiconductor component and the top surface of the second coated semiconductor component forming the device; and curing the device in a final cure step at a temperature of 200-450° C. for at least 1 hour. At least one of the first coating composition and the second coating composition includes a siloxane coating composition of the following formula:

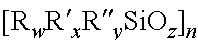

wherein R, R′, and R″ are each an alkyl group, an aryl group, a hydroxyl group, or an alkoxyl group; w is 0-1.5; x is 0-1.5; y is 0-1.5; z is 1.2-2; and n is 10-100,000. Any of R, R′, or R″ may also contain a reactive functional group, wherein the alkyl group and/or the aryl group may each independently include one or more polar protic or aprotic functional groups selected from, but not limited to, hydroxyl, amino, or carboxyl functionalities.

### BRIEF DESCRIPTION OF THE DRAWINGS

The above-mentioned and other features and advantages of this disclosure, and the manner of obtaining them, will become more apparent, and will be better understood by reference to the following description of the exemplary embodiments taken in conjunction with the accompanying drawings, wherein:

FIG. 1 is an exemplary process flow with key advantages over the PECVD oxide-based hybrid bonding prior art listed in each of several process steps.

FIG. 2A is an exemplary process flow for a single Damascene process with one spin-on dielectric layer.

FIG. 2B is an exemplary process flow for a dual Damascene process with two spin-on dielectric layers.

FIG. 3A shows an optional step in between step 5 and 6 of Process Flow #1, wherein the optional step may be added to deposit and pattern a second metallic thing film 151 on the top surface of the copper bonding pads 111.

FIG. 3B shows the resulting final structure of Process Flow #2, after bonding using the optional metallic interlayer consisting of an intermetallic layer 152 in between the copper bonding pads 109.

FIG. 4A shows the incoming wafer that is used in step 1 of Process Flow #3, a silicon or non-silicon wafer or singulated chip 101, consisting of multiple front-end-of-line (FEOL), mid-end-of-line (MEOL) and back-end-of-line (BEOL) copper-dielectric layers, wherein the dielectrics are typical on-chip dielectrics such as porous silicon oxides, silicon nitrides, silicon oxi-nitrides and other inorganic material.

FIG. 4B shows the result of step 2 of Process Flow #3, the structure of the resulting copper bond pads 111.

FIG. 4C shows the result of step 3 of Process Flow #3, the partially cured spin-on dielectric 106.

FIG. 4D shows the result of step 4 of Process Flow #3, the nano-scale smooth surface with the copper pad 111 slightly protruding from the dielectric surface by a few nanometers to a few hundred nanometers in thickness.

FIG. 4E shows the final structure of Process Flow #3, a final structure consisting of a fully cured siloxane coating composition layer 112 encapsulating ultra-fine pitch homogeneous copper interconnects.

FIG. 5 is an exemplary optimized process flow for spin-on dielectric with spin on dielectric as underlying RDL dielectric layer.

FIG. 6 shows the result of Process Flow #3C. In particular, the intermetallic layer 152 in between the copper bonding pads.

FIG. 7 shows optimized process flow wherein copper pad formation occurs prior to spin on dielectric deposition.

Corresponding reference characters indicate corresponding parts throughout the several views. Although the drawings represent embodiments of various features and components according to the present disclosure, the drawings are not necessarily to scale and certain features may be exaggerated in order to better illustrate and explain the present disclosure. The exemplification set out herein illustrates an embodiment of the disclosure, and such an exemplification is not to be construed as limiting the scope of the disclosure in any manner.

### DETAILED DESCRIPTION

For the purpose of promoting an understanding of the principles of the present disclosure, reference is now made to the embodiments illustrated in the drawings, which are described below. The exemplary embodiments disclosed herein are not intended to be exhaustive or to limit the disclosure to the precise form disclosed in the following detailed description. Rather, these exemplary embodiments were chosen and described so that others skilled in the art may utilize their teachings.

A major trend in advanced semiconductor packages is the continuing increase in chip-to-chip interconnect density or I/O density, primarily achieved by decreasing the diameter and pitch of electrical connections, commonly referred to as bumps or micro bumps. Traditionally, lead-free solder alloys have been used to form such die to substrate, die to interposer or die to die bump connections. However, due to the excessive flow of such solders during reflow at temperatures (typically 250-260° C.), chip to chip connections migrated to copper pillar micro bumps with lead-free solder “caps” to reduce the amount of reflow and continue to scale down the micro bump pitch. In recent years, such copper-solder micro bumps have been demonstrated down to 20-40 micrometer bump pitches. With the advent of AI enabled high performance computing and 2.5D/3D integration of logic and high bandwidth memory (HBM) chip-on-wafer bonding, the I/O pitch scaling need has accelerated with sub-10 micrometer pitches required for large silicon area integration on one interposer or package. This necessitated the move to Cu—Cu direct bonding approaches such as hybrid bonding to eliminate the limitations of solder reflow. The most common method of Cu—Cu direct bonding is “hybrid bonding”, a method that combines dielectric-to-dielectric bonding using SiO₂ back end of line dielectric layers fusion bonded to each other, followed by or concurrently achieving Cu—Cu diffusion bonding at high temperatures in inert and high vacuum environments. Hybrid bonding has several advantages in pitch scaling compared to conventional solder based micro bump thermo-compression bonding (TCB). The most important benefit of dielectric-copper fusion hybrid bonding is the ability of the as-deposited oxide dielectrics after plasma activation to achieve sufficient bonding strength without significant pressure to hold ultra-small copper micro bump structures on both die being stacked in place during the high temperature copper diffusion. During this metallurgical bonding step, the copper pad structures can be held to sub-micron alignment tolerances, achieving micro bump pitches as small as 2-10 micrometers.

Hybrid bonding usually refers to the three-step wafer-to-wafer process that includes:
(a) dielectric-to-dielectric bonding (i.e., silicon dioxide-to-silicon dioxide bonding) at low/room temperature;
(b) heating to close the gap between the interfaces; depending on the type of dielectric being used with copper conductors, the mismatch in coefficient of thermal expansion, CTE, of metal versus the dielectric must be addressed through producing a surface with recessed or protruding copper; closing the gap between conductive metal pads when using silicon dioxide as the dielectric, or alternatively to close the gap between dielectric surfaces when using carbon-based polymeric materials as the dielectric; and
(c) further heating to bond the dielectric and conductive metal pads with or without external pressures.

Bonding between silicon oxide surfaces proceeds generally in the following process sequence:
1) formation of dangling bonds and bonding between hydroxyl groups and water molecules through plasma activation using gases such as O₂ (oxygen)/N₂ (nitrogen)/Ar (argon);
2) removal of defects through deionized water cleaning and scrubbing;
3) bonding of wafers (or wafer and wafer-sized interposer) with similar oxide bonding layers at room temperature and atmospheric pressure via van der Waals hydrogen bonds between two to three mono-layers of water molecules and polar hydroxyl (OH) groups (which terminate at both the native and thermal SiO₂);
4) formation of van der Waals bonds between H₂O molecules and silanol groups (Si—OH—(H₂O)ₓ—HO—Si; silanol group ═Si—OH) on wafer surfaces; and
5) annealing to remove water molecules at the interface and form covalent bonds at temperatures typically less than 400° C. (and preferably below 250° C.) to prevent melting of the inter-metal layers and diffusion of implanted dopant.

Conventional packaging includes a frontside to backside (F2B) attachment, i.e., attaching a frontside surface of a semiconductor die or stacks of semiconductor dies on a backside surface of a semiconductor wafer through hybrid bonding. Hybrid bonding processes rely on chemical bonds and interactions between interfacing surfaces of the semiconductor dies and the interface wafer. For example, intermolecular interactions including van der Waals forces, hydrogen bonds, and strong covalent bonds can be formed in the hybrid bonding process to join dielectric-dielectric surfaces as well as metal-metal interfaces at high temperatures and/or compression pressures. Further, the bonding interface between the semiconductor dies and semiconductor wafer may be affected by thermal cycles, e.g., anneal temperatures, that are applied during the hybrid bonding process.

Packaging processes utilize a post bond thermal anneal process to achieve a gap free metal-metal bonding at the interface between the bond pads of stacked semiconductor die or wafers. One of the challenges for conventional hybrid bonding is that the post bond anneal temperature is limited by the materials and cannot form a conjoined metal-metal bonding interface between the bond pads. Further, macro bumps included in the semiconductor wafer may contain solder materials which may melt at a temperature that is higher than 260° C. Moreover, the limited temperature of post bond anneal thermal cycles, e.g., 300° C., is not high enough to form a gap/void free metal-metal bonding interface in the 3D stack and may degrade device performance of the assembled semiconductor die or stacking of semiconductor dies. Another significant challenge exists in providing nanometer-scale control of device surfaces using chemical mechanical planarization processes to overcome the shortcomings of HI with heterogenous surfaces of varied materials such as dielectrics and conductors.

In the case of oxide-to-oxide bonding, one can also vary oxide type and deposition technique, process conditions such as plasma gas, plasma power, surface roughness pertaining to chemical mechanical polish (CMP), surface cleanliness, mono- to multiple layers of water molecules from deionized cleaning, bonding conditions (such as temperature and speed), and anneal conditions (e.g., anneal temperatures, anneal time and number of annealing steps) to maximize the bonding yield and shear strength between two wafers.

When performing the wafer bonding process, commercially available wafer-to-wafer bonders can be used for low temperature (e.g., room temperature) dielectric-to-dielectric bonding. Typically, this involves using ions or neutral atoms in a vacuum to physically remove the oxide films on the dielectric surfaces of the wafers or substrates to be bonded and form dangling bonds on the surfaces, which subsequently enable direct bonding.

To achieve high wafer bonding yield when performing the wafer bonding process as described herein, the bonding surfaces can be cleaned using a fast atom beam (FAB) gun (e.g., by using argon, Ar, neutral atom beam) or ion gun (e.g., by using Ar ion) to remove the oxide film, for instance, on the wafer surface in vacuum and to create dangling bonds at the surfaces. FAB works well for Si/Si, Si/SiO₂, metals, compound semiconductors, and single crystal oxides, while an ion gun is known to work for SiO₂/SiO₂, Glass, SiN/SiN, Si/Si, Si/SiO₂, metals, compound semiconductor, and single crystal oxide. In some embodiments, a vacuum of 10-6 Pa (pascal) is required during bonding to prevent re-adsorption to activated bonding surfaces above. Additionally, a surface roughness of about 1 nm Ra (arithmetic mean surface roughness) is preferred at the surfaces of the two wafers to be bonded. This level of Ra can be achieved by chemical mechanical polishing (CMP).

There are a variety of challenges arising in the development of gap fill processes for heterogenous integration. Conformality and void-free filling of gaps are needed to achieve uniform, homogeneous deposition of dielectric materials in high aspect ratio gaps and complex 3D structures (e.g., trenches, vias, or spaces between chiplets). Voids or seams can lead to reliability issues, such as poor insulation or stress concentration points. Techniques like chemical vapor deposition (CVD) are prone to incomplete gap filling and can compromise electrical performance and mechanical stability, particularly in stacked architectures.

Heterogeneous integration often involves materials with differing CTEs, and the dielectric must act as a buffer while maintaining adhesion. Mismatched CTEs can lead to warpage, interfacial failure, or reduced device lifespan, especially under operational temperature fluctuations. Neither conventional CVD deposited silicon dioxide nor organic polymers have a coefficient of thermal expansion (CTE) sufficiently close to adjacent materials (e.g., silicon, metals, or other semiconductors) to avoid stress-induced cracking or delamination during thermal cycling.

To minimize parasitic capacitance and signal delay in high frequency or high-speed devices, dielectric materials with low dielectric constants (low k) are preferred. This is becoming increasingly important for 3D ICs as the dimensions are quickly scaling toward legacy interconnect technology. However, as in legacy interconnect technology, the dielectric materials must be compatible with the thermal budget and chemical environment of the heterogeneous integration process.

Heterogeneous integration often involves combining dies with different functionalities (e.g., CPU, GPU, and HBM memory). RDLs on an interposer or substrate facilitate high bandwidth and low latency communication between these components. RDLs provide short, high density electrical pathways between stacked or side-by-side dies, such as chiplets, memory, or sensors. The requirements for dielectric materials and processes for RDLs are quite similar to Gap Fill as a result of similar process integration schemes and performance requirements.

The manufacturing of ReDistribution Layers (RDLs) technology in semiconductor manufacturing typically involves several key steps, including the deposition, cleaning, patterning, etching, and metallization of a dielectric material. Legacy packaging at large dimensions has used organic polymers as the dielectric for cost and simplicity. However, advanced packaging devices with the requisite feature sizes in single digit micron and below needed for advanced packaging are migrating to more traditional back-end-of-line/interconnect technology using low k dielectrics. There is an inherent advantage to providing a spin-on inorganic dielectric material from cost and manufacturing simplicity perspectives. With reduced pitch and higher I/O densities, lower dielectric constant materials provide benefit in system performance. Further, by providing a material with CTE closely matching that of copper is expected to provide reduced stress during manufacturing and higher device lifetime and reliability.

Silicon oxide deposited by CVD offers several advantages as a dielectric material heterogenous integration. However, potential challenges related to stress, temperature sensitivity, and conformality need to be carefully addressed to ensure the reliability and manufacturability of the devices. Silicon oxide (SiO₂) is a well-established dielectric material with excellent electrical insulation properties, high breakdown voltage, and low dielectric constant. These properties are crucial for minimizing signal interference and ensuring reliable electrical performance in 3D integrated circuits. Chemical Vapor Deposition (CVD) is a mature and well controlled technique for depositing high quality silicon oxide films. CVD processes offer precise control over film thickness, uniformity, and composition, enabling the fabrication of reliable and reproducible dielectric layers for hybrid bonding. CVD deposited silicon oxide is compatible with many existing semiconductor fabrication processes, making it relatively easy to integrate into existing manufacturing workflows.

However, due to the high temperatures generally used during CVD deposition, the deposition process itself can introduce stress within the film or at the interface between silicon oxide and the underlying substrate. This stress can lead to the formation of defects, such as voids or cracks, which can compromise the integrity of the bond and degrade device performance. Achieving uniform film thickness and good step coverage can be challenging. Poor conformality can lead to variations in film properties and potential reliability issues, and excessive requirements for Chemical Mechanical Planarization (CMP) process steps. Equipment used to produce CVD materials is generally complex and expensive, adding significant cost to the overall cost-of-ownership for 3D integration.

Providing insulating materials with lower dielectric constants in advanced packaging interconnects also further reduces capacitance, leading to faster signal propagation, decreased power consumption, and minimized crosstalk, all crucial for improving device performance and enabling smaller, faster electronics. As device dimensions for advanced packaging continue to shrink, the need for materials with lower dielectric constants than SiO₂ are required.

Polyimide (PI)-to-PI hybrid bonding can be achieved based on a dielectric such as a fully cured PI with PI/Cu RDL layers on the mating surfaces under the application of external pressure during hybrid bonding. One can maximize the shear strength by varying conditions such as volume of water introduced, bonding time, and oxygen (O₂) plasma activation time. To achieve void free PI-to-PI bonding, it is important to activate the PI surfaces by oxygen plasma activation to generate low density hydrophilic groups on the PI surface which effectively enhances adsorption of water molecules introduced by a de-ionized water wetting process. The adsorbed water molecules, in turn, brings in consider-able high-density OH (hydroxyl) groups which facilitate prebonding. Following PI surface activation and wetting, PI-to-PI hybrid bonding can take place at a relatively low temperature of or below 250° C. for a few minutes. Neither the plasma process nor the wetting or hydration process alone can achieve good bonding. Key parameters to manipulate to achieve good bond yield include plasma activation time, volume of water introduced, bonding temperature and bonding time. Oxide-to-oxide hybrid bonding requires high component flatness and surface cleanliness to avoid electrical interconnection fails due to silicon dioxide's high hardness and poor deformation characteristics. Compared to the conventional oxide-to-oxide hybrid bonding, PI-to-PI bonding allows for higher surface roughness and is more tolerant of component flatness due to the low modulus and more compliant characteristics of the Pls.

Polymer hybrid bonding for HI allows for lower bonding T, shorter times, and lower stresses. The presently disclosed spin-on inorganic polymers offer the benefit of higher thermal stability. It may be further desirable to activate the surface of the dielectric, such as by oxidative or reductive chemical and plasma processes, to accentuate the bonding process between devices. It is also known that organic polymers including PI and BCB are prone to degradation during common surface activation processes, while inorganic (e.g., silicate) dielectrics are more robust and will not etch during surface activation.

Spin-on polymer deposition offers several potential advantages for hybrid bonding in 3D integration, particularly in terms of conformality, stress relief, and low temperature processing. The major advantages of spin-on materials are the greater compositional control over the final material deposited. This includes electrical, thermal, mechanical, and chemical compatibility. Final dielectric materials can be tailored, such as reduced mechanical strength by tradeoff for reduced induced stress in the integrated device.

Spin-on Dielectric (SOD) excels at depositing films over complex 3D structures, filling gaps and conforming to uneven surfaces with high precision. SOD materials are specifically designed for planarization, effectively smoothing out surface irregularities. Many SOD processes can be performed at lower temperatures compared to CVD, which is crucial for minimizing thermal stress and damage to temperature sensitive devices. SOD typically involves simpler equipment and processes compared to CVD, potentially leading to lower capital costs and easier integration into existing manufacturing lines.

In addition to the benefits of SOD processing, the materials produced from SOD enable planarization across complex 3D topographies crucial for reliable bonding across uneven surfaces and intricate device structures. Materials with lower mechanical strength and higher toughness can further act as stress buffers, absorbing mechanical stresses that may arise from thermal expansion mismatches, processing variations, or external forces. This helps to prevent the formation of voids or cracks at the bond interface, enhancing long-term reliability. Spin-on processes also have tremendous process flexibility, including deposition of varying thicknesses from nanometers to tens of microns. For thick films spin-on processes provide higher throughput relative to CVD deposition processes. For nonplanar surfaces, spin-on processes provide the advantage of self-planarizing, enabling additional process efficiencies for adjacent integration steps, such as by reducing CMP processing.

Spin-on polymer deposition offers several advantages for hybrid bonding in 3D integration, particularly in terms of conformality, stress relief, and low-temperature processing. However, potential challenges related to contamination, mechanical weakness, and film uniformity need to be carefully considered and addressed to ensure the successful implementation of this technology. The performance of polymers as dielectric materials in 3D integration will depend heavily on the specific type of polymeric material. Historically, there are limited types of polymers used for semiconductor device manufacturing due to the requirements of electrical, thermal, and mechanical property requirements of integration. These include for example, Benzocyclobutene (BCB) and Polyimides (PI). It has been noted that organic polymer dielectrics may be prone to thickness control when depositing thin layers of material, which can further limit their use in applications requiring thin films. For advanced packaging the non-rigid nature of many organic polymers can negatively impact alignment of devices during subsequent processing, especially for processes using thermal energy such as bonding steps.

In general, polymers exhibit excellent conformality, enabling them to effectively fill gaps and conform to complex 3D topographies. This is crucial for reliable bonding across uneven surfaces and intricate device structures. Polymers can act as stress buffers, absorbing mechanical stresses that may arise from thermal expansion mismatches, processing variations, or external forces. This helps to prevent the formation of voids or cracks at the bond interface, enhancing long-term reliability. Spin-on deposition can effectively planarize surfaces, improving the overall surface smoothness and reducing the risk of voids or air entrapment during the bonding process and minimizing CMP processing. Typically spin-on deposition processes are performed at ambient temperatures, minimizing the risk of thermal damage to temperature sensitive devices.

Although polymers have the potential for integration into interconnect process flows, historically they have not gained traction due to the complexity of changing integration process relative to the conventional silicate-based dielectric. Polymers can also potentially introduce impurities or contaminants into the bonding interface, which may degrade the electrical performance or reliability of the devices. Therefore, additional interfacial layers of processes may be needed for organic polymers to be successfully integrated. The use of silicate-based dielectric formulations to create hybrid bonding layers for advanced packaging inherently provides the material benefits of a silicate dielectric with the process flexibility and tailorable materials properties of formulation-based chemistry.

Hybrid bonding & annealing at lower temperatures are very critical for specific device types, and it necessitates thorough characterization of low temperature curing polymers. This differs from the conventional high density chip stacking technology where bond interconnection utilizes an inorganic dielectric material like SiO₂ and copper metal and is the main focus for chip to wafer or wafer to wafer bonding approaches (see Lin et al, 2023 IEEE 73rd Electronic Components and Technology Conference (ECTC)). In this process, the wafer or chip is precisely aligned on wafer at room temperature and by using van der Waals forces, two chemically active silicate surfaces enable controlled alignment. The Cu joint formation requires thermal annealing at 350° C.~400° C. for one hour. After that, the Cu-to-Cu joint has enough interdiffusion to form a stable bond while the SiO₂-to-SiO₂ bonding interface is also strengthened. While these temperatures are limiting for most organic polymers due to thermal degradation, inorganic silicate-based polymers are thermally stable well beyond these temperatures.

Spin-on formulations for dielectric deposition offer the benefit of controllable and tailorable materials properties. For example, spin-on silicate-based polymer dielectrics are known for their ability to provide a breadth of thermal, mechanical, and electrical performance based upon the chemistry of the formulation. For example, during processes such as hybrid bonding by matching the coefficients of thermal expansion (CTE) of the dielectric material to that of the conductive material, such as copper can be advantageous can minimize stresses and have beneficial impact on device yield and reliability. There is also a benefit to processing, for example since the CTE SiO₂ is lower than that of copper, the chemical mechanical planarization process must be precisely controlled to provide recessed copper features (aka. “copper dishing”) such that during subsequent thermal bonding processing the surfaces of the SiO₂ dielectric and copper come into intimate contact precisely at the conditions required for bonding. For organic polymer dielectrics such as PI where the CTE is greater than copper the chemical mechanical planarization process must be precisely controlled to provide recessed dielectric features (aka. “copper protrusion”) such that during subsequent thermal bonding processing the surfaces of the organic polymer dielectric and copper come into intimate contact precisely at the conditions required for bonding.

Matching CTE between dielectric and copper provides for process and device simplification, reliability. According to Park et al (DOI: 10.1002/admt.202202134), “ . . . to increase thermal reliability, the CTE of 16.7 ppm/C of Cu and polymer should be made similar. Under these conditions, thermal stress does not occur at the bonding interface, even during reliability tests”. Further, from Park et al, the CTE of general epoxy composite shows to be ~60 ppm/C and decreases to 30 ppm/C when SiO₂ is contained at 45 vol %. In addition, it can be further reduced to 16 ppm/C at 75 wt % of SiO₂. These suggest that there can be optimum SiO₂ content to make the CTE of polymer equal to Cu. In other heterogeneous materials, a CTE of ~23-29 ppm/C was obtained with 50 vol % of TiO₂/SiO₂ hybrid filler and 23 ppm/C with 60 vol % of SiO₂/Si₃N₄ hybrid filler. However, heterogenous organic dielectric materials using a base matrix and fillers have had limited adoption due to the complexity of managing integration and the introduction of defects.

In the study by HUANG et al (DOI: 10.1109/JEDS.2024.3358830), a novel modified polyimide copolymer was developed with a lower CTE compared to previous works, which was achieved by the addition of a photosensitive group. The CTE was reduced from ~70 ppm/C to around 34 ppm/C. They also claim that the incorporation of amide groups in polyimides can further reduce the CTE.

The main advantage of such a hybrid bonding process over conventional Cu solder microbump thermo-compression bonding is the ability of the oxide-to-oxide bond to be very flat and coplanar, holding the copper pads in precise alignment (submicron accuracy) to enable ultrafine pitch interconnects. Exemplary Cu—Cu hybrid bonding has been demonstrated at 2-10 micrometer I/O pitch in the prior art. The primary limitations of current hybrid bonding methods are related to the high complexity, low throughput and high cost of equipment for key process steps such as the CMP step and the plasma activation and bonding steps. Lower temperature hybrid bonding using conventional spin-on organic dielectrics such as polyimide and BCB have been attempted to overcome the complexity of PECVD oxide-based hybrid bonding, however, such polymers cannot maintain the submicron alignment accuracy of the copper structures on the first and second die surfaces, resulting in significant limits to the Cu-to-Cu interconnect pitch that can be achieved.

The present disclosure overcomes the limitations of the prior art in PECVD oxide-based Cu—Cu ultrafine pitch bonding and die stacking using a set of novel spin-on dielectric materials, eliminating some of the steps such as the plasma activation, and significantly simplifying other steps such as the CMP polishing of the dielectric and copper. The spin-on dielectric formulations in this disclosure also overcome the pitch scaling limitations of polymer hybrid bonding methods in the prior art. This is achieved by a combination of a two-step bonding process, consisting of a first step at a lower temperature to partially cure the spin-on dielectric, enabling a high strength dielectric to dielectric bond without the need for plasma activation or complex CMP polishing to form copper recesses in the structures. A second bonding step at high temperatures enables the spin-on dielectric to fully cure to a set of mechanical properties close to that of PECVD silicon oxide, enabling the structures to maintain precise alignment during the copper-to-copper diffusion bonding step.

The present disclosure provides a semiconductor package comprising two semiconductor components bonded at a bonding layer. Each semiconductor component may comprise one of a wafer, die, chip, or an integrated device.

The bonding layer may comprise a first coating composition. The first coating composition may comprise a siloxane coating composition of formula (1):

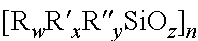

wherein R, R′, and R″ are each an alkyl group, an aryl group, a hydroxyl group, or an alkoxyl group, wherein the alkyl group and/or the aryl group may each independently include one or more polar protic or aprotic functional groups selected from, but not limited to, hydroxyl, amino, or carboxyl functionalities; w is 0-1.5; x is 0-1.5; y is 0-1.5; z is 1.2-2; and n is the number of repeating siloxane monomer units between 10-100,000. Any of R, R′, or R″ may also contain a reactive functional group.

The bonding layer may additionally comprise a second coating composition, such as a SiO₂ coating composition.

Further, the present disclosure provides a method of fusing the first and second semiconductor components together.

### I. First Coating Composition—Siloxane Coating Composition

The semiconductor package of the present disclosure may comprise at least one semiconductor component coated in a siloxane coating composition of formula (1):

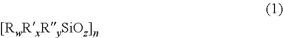

wherein R, R′, and R″ are each an alkyl group, an aryl group, a hydroxyl group, or an alkoxyl group, wherein the alkyl group and/or the aryl group may each independently include one or more polar protic or aprotic functional groups selected from, but not limited to, hydroxyl, amino, or carboxyl functionalities; w is 0-1.5; x is 0-1.5; y is 0-1.5; z is 1.2-2; and n is the number of repeating siloxane monomer units between 10-100,000. Any of R, R′, or R″ may also contain a reactive functional group.

The siloxane coating composition may comprise at least one silicon-based compound, a solvent, and, optionally, other additives.

Upon curing, the siloxane coating composition may form a siloxane coating.

### A. Silicon-Based Compound

The siloxane coating composition may comprise at least one silicon-based compound. The at least one silicon-based compound may comprise siloxane monomers, polysiloxanes, silsesquioxanes, and/or poly(silsesquioxanes).

The at least one silicon-based compound may comprise siloxane monomer units of formula (2):

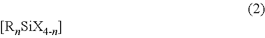

wherein R is an alkyl group, an aryl group, or an alkoxyl group, wherein the alkyl group and/or the aryl group may each independently include one or more polar protic or aprotic functional groups selected from, but not limited to, hydroxyl, amino, or carboxyl functionalities;
X is a hydrolysable group selected from an alkoxy group, —OR group, an acetoxy group, or a halogen including Cl, I, Br, or F; and
n is 0, 1, 2, or 3.

Each siloxane monomer may be described according to the degree of oxygen substitution, or functionality, on the central silicon atom, as shown in Table A.

TABLE A
Siloxane Monomer Types

| Structural formula | Functionality | Symbol |
|---|---|---|
| R₃Si—O— | Monofunctional | M |
| 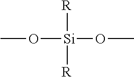 | Difunctional | D |
| 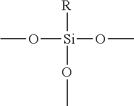 | Trifunctional | T |
| 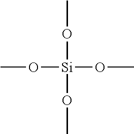 | Tetrafunctional | Q |

Silane monomers are not limited to siloxanes as polysiloxanes can be derived from other silanes with labile functionalities such as CI, Acetoxy, peroxy, which can be in situ converted to Si—O structures of the repeating units.

The siloxane monomer of the silicon-based compound may be a monofunctional, difunctional, or trifunctional siloxane monomer.

Suitable monofunctional siloxane monomers (M units) may include trimethylmethoxy silane, and trimethylethoxy silane.

Suitable difunctional siloxane monomers (D units) may include diethoxydiphenyl silane, methylphenyldiethoxy silane, diethoxydimethyl silane, dimethyldimethoxy silane, diphenyldimethoxy silane, diphenyldiethoxy silane, methylphenyldimethoxy silane, dimethyldiethoxy silane, diphenyldiethoxy silane, and methylphenyldiethoxy silane.

Suitable trifunctional siloxane monomers (T units) may include methyltrimethoxy silane, methyltriethoxy silane, phenyltrimethoxy silane, phenyltriethoxy silane, ethyltrimethoxy silane, propyltrimethoxy silane, methyltriethoxy silane, and propyltriethoxy silane.

Suitable tetrafunctional siloxane monomers (Q units) may include tetraethoxy silane and tetramethoxy silane.

The silicon-based compound may include polymerized siloxane monomers or a polysiloxane.

A siloxane is a chemical compound having branched or unbranched backbones consisting of alternating silicon and oxygen atoms —Si—O—Si—O— with side chains R attached to the silicon atoms (R¹R²SiO), where R is a hydrogen atom or a hydrocarbon group. Polysiloxanes may include oligomeric and/or polymeric siloxane monomer units, optionally having organic side chains, which may be represented by formula (3) shown below, where “n” indicates a repeat unit greater than 1:

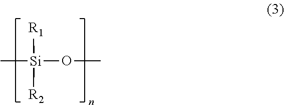

wherein n is at least 3 and less than 10,000.

In addition to hydrogen, R¹ and R² of polysiloxane are independently selected from the group consisting of an alkyl group, an aryl group, an alkoxyl group, an acetoxy group, or a halogen including Cl, I, Br, or F, wherein the alkyl group and/or the aryl group may each independently include one or more polar protic or aprotic functional groups selected from, but not limited to, hydroxyl, amino, or carboxyl functionalities.

By varying the —Si—O— chain lengths, side groups, and crosslinking, polysiloxanes can vary in consistency from liquid to gel to rubber to hard plastic.

Representative examples of polysiloxane are [SiO(CH₃)₂]ₙ (polydimethylsiloxane, PDMS) and [SiO(C₆H₅)₂]ₙ (polydiphenylsiloxane). For example, the silicon-based coating composition may include polydimethylsiloxane having the chemical structure shown below.

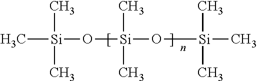

The coating composition may be initially formulated with one or more polysiloxanes resulting from condensation reactions of siloxane monomers of Formula (1). Further, the siloxane monomers may form a polysiloxane, as described above, and then further react with a polysilsesquioxanes, described below.

The silicon-based compound may include polymerized silsesquioxanes and poly(silsesquioxanes).

Silsesquioxanes are cage-like molecules containing silicon and oxygen atoms. Their polymerization process links the cage-like units to form a larger, three-dimensional polymer network. The silsesquioxane polymer may include poly(methylsilsesquioxane) monomers with the formula [RSiO_{3/2}]ₙ, wherein R is a hydrogen, an alkyl group, an aryl group, or an alkoxyl group, wherein the alkyl group and/or the aryl group may each independently include one or more polar protic or aprotic functional groups selected from, but not limited to, hydroxyl, amino, or carboxyl functionalities. For example, the polysilsesquioxane monomers can include poly(methylsilsesquioxane) blocks, poly(phenylsilsesquioxane) blocks, poly(methylphenylsilsesquioxane) or any combinations thereof.

Suitable commercially available polysilsesquioxane resins include GR650F resin, GR100F resin, GR150F resin, and GT950F resin obtainable from Techneglas of Perrysburg, Ohio.

The GR150F and GR100F resins comprise, consist essentially of, or consist of poly(phenylsilsesquioxane) blocks and poly(methylsilsesquioxane) blocks.

The GR950F resin comprises, consists essentially of, or consists of poly(phenylsilsesquioxane) blocks.

The GR650F resin comprises, consists essentially of, or consists of poly(methylsilsesquioxane) blocks.

The silicon-based compound may have a molecular weight from about 1000 g/mol, about 1500 g/mol, or about 2000 g/mol to about 5000 g/mol, about 25000 g/mol, about 100000 g/mol, or about 1000000 g/mol or any range using any two of the foregoing values as end points, such as 1000 to 100000 g/mol, 100,000 to 100000 g/mol, 1500 to 25000 g/mol, 25000 to 1000000 g/mol, 500000 to 100000 g/mol or 2000 to 5000 g/mol, as determined by gel permeation chromatography (GPC) using polystyrene standards.

The siloxane coating composition may comprise a total amount of silicon-based compound from about 10 wt. %, about 15 wt. %, or about 20 wt. % to about 30 wt. %, about 40 wt. %, or about 50 wt. %, or any range using any two of the foregoing values as endpoints, such as 10 to 50 wt. %, 15 to 40 wt. %, or 20 to 30 wt. %, based on the total weight of the siloxane coating composition.

### B. Solvent

The siloxane coating composition may comprise a solvent. Suitable solvents may include, but are not limited to, aromatic hydrocarbons; aliphatic hydrocarbons, such as, hexane, heptane, benzene, toluene, branched-chain alkanes (isoparaffins); halogenated hydrocarbons; esters, such as methyl acetate, n-butyl acetate, tert-butyl acetate, isobutyl acetate, sec-butyl acetate, ethyl acetate, amyl acetate, pentyl acetate, 2-methyl butyl acetate, isoamyl acetate, n-propyl acetate, isopropyl acetate, ethylhexyl acetate; ketones, such as acetone or methyl ethyl ketone; ethers, such as tetrahydrofuran, dibutyl ether; and mono- and polyalkylene glycol dialkyl ethers (glymes) or mixtures of these solvents may be used.

The siloxane coating composition may comprise an amount of solvent from about 50 wt. %, about 60 wt. %, or about 70 wt. % to about 80 wt. %, about 85 wt. %, or about 90 wt. %, or any range using any two of the foregoing values as endpoints, such as 50 to 90 wt. %, 60 to 85 wt. %, or 70 to 80 wt. %, based on the total weight of the siloxane coating composition.

### C. Crosslinkers

The siloxane coating composition may comprise a crosslinker. The crosslinker may include a siloxane compound according to the general formula (4):

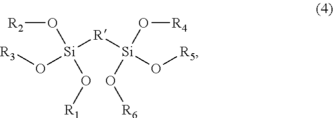

Additionally, suitable crosslinkers may have one of the following formulas (5)-(11):

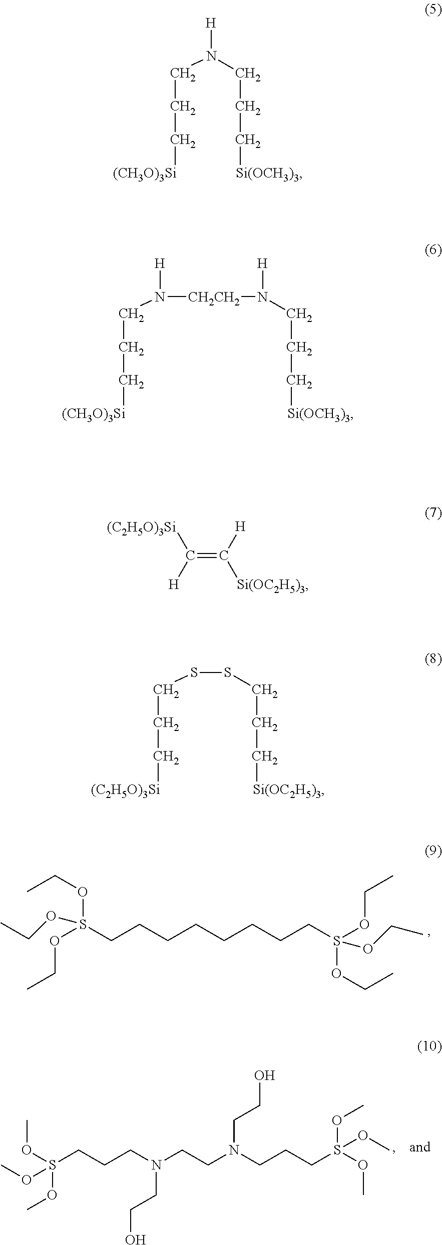

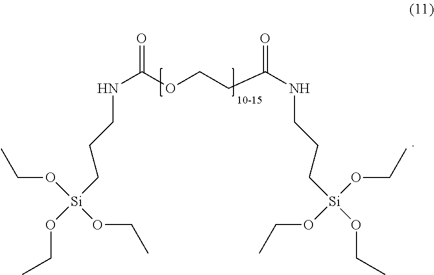

The crosslinker may be bis-(trimethoxysilylpropyl)amine (Formula VI), N,N′ bis(trimethoxysilylpropyl)ethylenediamine, (Formula VII), 1,2-bis(trimethoxysilyl)ethylene, (Formula VIII); bis [3-(triethoxysilyl) propyl]disulfide (Formula IX), bis-(triethoxysilylpropyl)amine, bis-(methyldimethoxysilylpropyl)amine, bis-(methyldiethoxysilylpropyl)amine, bis(trimethoxysilyl) methane, bis(triethoxysilyl) methane, 1,2-bis(triethoxysilyl) ethane, bis(trimethoxysilyl)benzene, bis(triethoxysilyl)benzene, or 1-(triethoxysilyl)-2-(diethoxymethylsilyl) ethane, 1,8-bis(triethoxysilyl) octane (Formula X), N,N′-bis(2-hydroxyethyl)-N,N′-bis(trimethoxysilylpropyl)ethylenediamine (Formula XI), N,N′-bis-[(3-triethoxysilylpropyl)aminocarbonyl]polyethylene oxide (Formula XII), or any combinations thereof. Such crosslinkers have high functionality to provide a greater chance of linking together high molecular weight chains, as well as low molecular weight oligomers.

Without wishing to be bound by any theories, it is believed that without crosslinkers as described above, high molecular weight chains cross-link directly, producing rigid structures that build up high stresses after high temperature exposure. It is further believed that insufficiently bonded low-molecular weight oligomers make the coatings weaker and more likely to crack due to the build-up of high stresses in the film. The high functionality crosslinkers bond together the high molecular weight chains at more locations to provide extra strength, while the aliphatic comprising group of the crosslinkers provides flexibility between the chains to reduce film stress. The high functionality crosslinkers also bond to more of the low-molecular weight oligomers, acting as chain extenders to increase the molecular weight of the film and increase the film strength. Thus, planarizing films may be able to resist cracking, even at thickness exceeding 6 microns and after exposure to temperatures exceeding 400° C.

The siloxane coating composition may comprise an amount of crosslinkers from about 0 wt. %, about 1 wt. %, or about 2 wt. % to about 3 wt. %, about 4 wt. %, or about 5 wt. %, or any range using any two of the foregoing values as endpoints, such as 0 to 5 wt. %, 1 to 4 wt. %, or 2 to 3 wt. %, based on the total weight of the siloxane coating composition.

### D. Additives

The siloxane coating composition may optionally comprise a plurality of additives. Suitable additives may include catalysts, surfactants, adhesion promoters, plasticizers, organic acids, and monofunctional silanes.

The total amount of additives in the siloxane coating composition may be from about 0 wt. %, about 2 wt. %, or about 4 wt. % to about 15 wt. %, about 30 wt. %, or about 50 wt. %, or any range using any two of the foregoing values as endpoints, such as 0 to 50 wt. %, 2 to 30 wt. %, or 4 to 15 wt. %, based on the total weight of the siloxane coating composition.

### II. Second Coating Composition

The bonding layer may comprise a second coating composition in addition to the siloxane coating composition. This second coating composition may be applied to the second semiconductor component in lieu of the siloxane coating composition.

The second coating composition may comprise SiO₂, SiCN, a polymer coating composition, or any other suitable coating composition.

### III. Semiconductor Package

The present disclosure provides a semiconductor package comprising a first semiconductor component and a second semiconductor component.

Each of the first semiconductor component and the second semiconductor component may comprise one of a wafer, die, chip, or an integrated device.

The semiconductor package of the present disclosure may be formed using various bonding configurations, including wafer-to-wafer (W2 W), die-to-wafer (D2 W), and die-to-die (D2D) bonding. In W2 W bonding, two full wafers are aligned and bonded together, which may provide high throughput and precise alignment across the entire wafer surface. In D2 W bonding, also referred to as chip-on-wafer (CoW), individual dies are picked and placed onto a target wafer, which may allow for known-good-die (KGD) selection and heterogeneous integration of dies from different wafer sources. In D2D bonding, also referred to as chip-on-chip (CoC), individual dies are bonded directly to each other, which may be suitable for smaller scale integration or specialized applications. Each bonding configuration may utilize frontside-to-frontside (F2F) or frontside-to-backside (F2B) orientations depending on the device architecture and interconnect requirements. The spin-on siloxane coating compositions and methods described herein may be applied to any of these bonding configurations.

A top surface of the first semiconductor component may be coated with a first coating composition. The first coating composition may be the siloxane coating composition described above. A top surface of the second semiconductor component may be coated with a second coating composition. The second coating composition may be one of the siloxane coating composition, a silicon dioxide (SiO₂) coating composition, a SiCN coating composition, a polymer coating composition, or any other suitable coating composition. The method of application of the coating compositions on the first and second semiconductor components is described below.

Each of the semiconductor components may comprise at least one copper interconnect. The at least one copper interconnect may comprise a copper pad at the base of the copper interconnect, a copper via coupled to the copper pad, and a copper bonding pad at the top of the copper interconnect opposite the copper pad. The copper interconnects are configured to establish an electrical connection between the first semiconductor component and the second semiconductor component. When the second semiconductor component is stacked onto the first semiconductor component, the at least one copper interconnect of the first semiconductor component and the at least one copper connect of the second semiconductor component may align such that the copper bonding pad of each copper interconnect meet at an interface and may establish an electrical connection.

A device, such as an electronic chip or “stacked wafer/semiconductor component”, may be formed by stacking the first semiconductor component and the second semiconductor component such that the coating composition of each semiconductor component meet at an interface and bond together during final cure, forming a bonding layer. The bonding layer may comprise a first coating composition, the siloxane coating composition, of the first semiconductor component and the second coating composition of the second semiconductor component. The second coating composition may be either the siloxane coating composition or the SiO₂ coating composition, or any suitable coating.

### IV Method—Application and Cure

### A. Application

The first semiconductor component may have the first coating composition, such as a siloxane coating composition, spin coated onto the top surface of the first semiconductor component. The second semiconductor component may have a second coating composition applied onto the top surface of the second semiconductor device. The second coating composition may comprise one of a siloxane coating composition spin coated onto the top surface of the second semiconductor component, a SiO₂ coating composition applied using chemical vapor deposition (CVD) onto the top surface of the second semiconductor component, or another suitable second coating composition applied to the top surface of the second semiconductor component.

i. Siloxane Coating Composition Application—Spin Coating

The siloxane coating composition may be applied to a semiconductor component using spin-coating techniques.

A layer of the siloxane coating composition is applied to the top surface of the semiconductor component. The semiconductor component may then rapidly spun to spread the coating composition evenly across the top surface of the semiconductor component. The spin coating application comprises spinning the semiconductor component at a speed of at least 500 revolutions per minute (rpm), at least 700 rpm, at least 800 rpm, at least 900 rpm, at least 1000 rpm, or at least 1100 rpm, or any range using any two of the foregoing values as endpoints, such as 500 to 1100 rpm, 700 to 1000 rpm, or 800 to 900 rpm.

ii. Pre-Curing the Siloxane Coating Composition

The siloxane coating composition may be pre-cured.

The siloxane coating composition may be pre-cured at a temperature from about 40° C., about 50° C., or about 60° C. to about 70° C., about 80° C., or about 100° C., or any range using any two of the foregoing values as endpoints, such as 40° C. to 100° C., 50° C. to 80° C., or 60° C. to 70° C. for a period from about 10 sec, about 20 sec, or about 30 sec to about 40 sec, about 50 sec, or about 60 sec, or any range using any two of the foregoing values as endpoints, such as 10 to 60 sec, 20 to 50 sec, or 30 to 40 sec.

Alternatively, in a second embodiment, the siloxane coating composition may be pre-cured at room temperature, or about 20° C. to 25° C., for a period from about 10 min, about 20 min, or about 30 min to about 40 min, about 50 min, or about 60 min, or any range using any two of the foregoing values as endpoints, such as 10 to 60 min, 20 to 50 min, or 30 to 40 min.

In a third embodiment, the siloxane coating composition may be pre-cured in a two-step process. In a first step of the two-step pre-curing process, the siloxane coating composition may be pre-cured at a temperature from about 100° C., about 120° C., or about 130° C. to about 150° C., about 170° C., or about 175° C., or any range using any two of the foregoing values as endpoints, such as 100° C. to 175° C., 120° C. to 170° C., or 130° C. to 150° C. for a period from about 0.5 min, about 1 min, or about 1.5 min to about 2 min, about 3 min, or about 5 min, or any range using any two of the foregoing values as endpoints, such as 0.5 min to 5 min, 1 to 3 min, or 1.5 to 2 min. In a second step of the two-step pre-curing process, the siloxane coating composition may be pre-cured at a temperature from about 140° C., about 150° C., or about 160° C. to about 170° C., about 180° C., or about 200° C., or any range using any two of the foregoing values as endpoints, such as 140° C. to 200° C., 150° C. to 180° C., or 160° C. to 170° C. for a period from about 0.5 min, about 1 min, or about 1.5 min to about 2 min, about 3 min, or about 5 min, or any range using any two of the foregoing values as endpoints, such as 0.5 min to 5 min, 1 to 3 min, or 1.5 to 2 min.

In a fourth embodiment, the siloxane coating composition may be pre-cured in a three-step process. In a first step of the three-step pre-curing process, the siloxane coating composition may be pre-cured at a temperature from about 100° C., about 120° C., or about 130° C. to about 150° C., about 170° C., or about 175° C., or any range using any two of the foregoing values as endpoints, such as 100° C. to 175° C., 120° C. to 170° C., or 130° C. to 150° C. for a period from about 0.5 min, about 1 min, or about 1.5 min to about 2 min, about 3 min, or about 5 min, or any range using any two of the foregoing values as endpoints, such as 0.5 min to 5 min, 1 to 3 min, or 1.5 to 2 min. In a second step of the three-step pre-curing process, the siloxane coating composition may be pre-cured at a temperature from about 140° C., about 150° C., or about 160° C. to about 170° C., about 180° C., or about 200° C., or any range using any two of the foregoing values as endpoints, such as 140° C. to 200° C., 150° C. to 180° C., or 160° C. to 170° C. for a period from about 0.5 min, about 1 min, or about 1.5 min to about 2 min, about 3 min, or about 5 min, or any range using any two of the foregoing values as endpoints, such as 0.5 min to 5 min, 1 to 3 min, or 1.5 to 2 min. And in a third step of the three-step pre-curing process, the siloxane coating composition may be pre-cured at a temperature from about 200° C., about 220° C., or about 240° C. to about 250° C., about 280° C., or about 300° C., or any range using any two of the foregoing values as endpoints, such as 200° C. to 300° C., 220° C. to 280° C., or 240° C. to 250° C. for a period from about 1 min, about 2 min, or about 4 min to about 6 min, about 8 min, or about 10 min, or any range using any two of the foregoing values as endpoints, such as 1 min to 10 min, 2 to 8 min, or 4 to 6 min.

In a fifth embodiment, following the one-step, two-step, or three-step pre-cure process, the siloxane coating composition may optionally undergo a pre-CMP cure at a temperature of about 200° C., about 250° C., or about 300° C. to about 350° C., about 400° C., or about 450° C., or any range using any two of the foregoing values as endpoints, such as 200° C. to 450° C., 250° C. to 400° C., or 300° C. to 350° C. for a period of time of at least 0.5 hours, at least 1.0 hours, at least 2 hours, or at least 3 hours, or any range using any two of the foregoing values as endpoints, such as 0.5 to 3 hours, or 1.0 to 2 hours.

In a sixth embodiment, at any step of the bake process, the siloxane coating composition may optionally be exposed to ultraviolet radiation.

Following curing of the siloxane coating composition using any one of the six embodiments described above, the siloxane coating composition may have a film thickness (FT) of about 0.1 μm, 0.4 μm, about 1.0 μm, or about 1.5 μm to about 3.0 μm, about 5.0 μm, or about 7.0 μm, or any range using any two of the foregoing values as endpoints, such as 0.1 μm to about 1.0 μm, about 0.2 μm to about 3 μm, 0.4 to 7.0 μm, 1.0 to 5.0 μm, or 1.5 to 3.0 μm, as measured using a Woollam M-2000 spectroscopic ellipsometer, a Filmetrics F-50 film thickness measurement mapping instrument, or an Atlas Instrument from Onto Innovation, formerly Nanometrics, which uses spectroscopic reflectometry and ellipsometry to measure thin film thickness.

iii. SiO₂ Coating Composition—Chemical Vapor Deposition

A SiO₂ coating composition may be applied to the top surface of the second semiconductor component by chemical vapor deposition (CVD) with silane (SiH₄) and oxygenated reactant (such as oxygen and ozone) gases under plasma conditions. CVD is a process of depositing a coating composition onto a surface through chemical reaction of gaseous precursors. Under plasma conditions, the gases are ionized to create a highly reactive environment, allowing for precise control of film properties.

Upon curing, the SiO₂ coating composition may form a SiO₂ coating.

The SiO₂ coating may have a film thickness (FT) of about of about 0.1 um, 0.4 um, about 1.0 um, or about 1.5 um to about 3.0 um, about 5.0 um, or about 7.0 um, or any range using any two of the foregoing values as endpoints, such as 0.1 um to about 1.0 um, about 0.2 um to about 3 um, 0.4 to 7.0 um, 1.0 to 5.0 um, or 1.5 to 3.0 um, as measured using a Woollam M-2000 spectroscopic ellipsometer, a Filmetrics F-50 film thickness measurement mapping instrument, or an Atlas Instrument from Onto Innovation, formerly Nanometrics, which uses spectroscopic reflectometry and ellipsometry to measure thin film thickness.

### B. Final Cure

Once both the first and second semiconductor components are coated with either the siloxane coating composition or the SiO₂ coating composition, first and second semiconductor component may be stacked such that the top surface of the first coated semiconductor component and the top surface of the second coated semiconductor component are contacted together at an interface. When the first and second semiconductor components are stacked, the copper interconnects of the first semiconductor component may match up with the copper contacts of the second semiconductor component, forming an electrical connection between the first and second semiconductor components.

The device may then undergo final cure at a temperature of about 200° C. about 250° C., or about 300° C. to about 350° C., about 400° C., or about 450° C., or any range using any two of the foregoing values as endpoints, such as 200° C. to 450° C., 250° C. to 400° C., or 300° C. to 350° C. for a period of time of at least 0.5 hours, at least 1.0 hours, at least 2 hours, or at least 3 hours, or any range using any two of the foregoing values as endpoints, such as 0.5 to 3 hours, or 1.0 to 2 hours. The final cure step may form a bonding layer comprising the siloxane coating and, optionally, the SiO₂ coating.

During final cure, pressure may be applied to the device. The applied pressure may be about 1 kPa, about 10 kPa, or about 100 kPa, to about 20 MPa, about 100 MPa, or about 500 MPa, or any range using any two of the foregoing values as endpoints, such as 1 kPa to 500 MPa kg, or 10 kPa to 100 MPa, or 100 kPa to 20 MPa. Table B below provides exemplary combinations of final cure temperatures, times, and pressures that may be used in the final cure step of the method described herein.

TABLE B
Final Cure Temperature and Pressure Combinations

| Final Cure Temperature | Final Cure Time | Applied Pressure |
|---|---|---|
| about 200° C. | at least 0.5 hours | about 1 kPa |
| about 200° C. | at least 0.5 hours | about 10 kPa |
| about 200° C. | at least 0.5 hours | about 100 kPa |
| about 200° C. | at least 0.5 hours | about 20 MPa |
| about 200° C. | at least 0.5 hours | about 100 MPa |
| about 200° C. | at least 0.5 hours | about 500 MPa |
| about 200° C. | at least 1.0 hours | about 1 kPa |
| about 200° C. | at least 1.0 hours | about 10 kPa |
| about 200° C. | at least 1.0 hours | about 100 kPa |
| about 200° C. | at least 1.0 hours | about 20 MPa |
| about 200° C. | at least 1.0 hours | about 100 MPa |
| about 200° C. | at least 1.0 hours | about 500 MPa |
| about 250° C. | at least 0.5 hours | about 1 kPa |
| about 250° C. | at least 0.5 hours | about 10 kPa |
| about 250° C. | at least 0.5 hours | about 100 kPa |
| about 250° C. | at least 0.5 hours | about 20 MPa |
| about 250° C. | at least 0.5 hours | about 100 MPa |
| about 250° C. | at least 0.5 hours | about 500 MPa |
| about 250° C. | at least 1.0 hours | about 1 kPa |
| about 250° C. | at least 1.0 hours | about 10 kPa |
| about 250° C. | at least 1.0 hours | about 100 kPa |
| about 250° C. | at least 1.0 hours | about 20 MPa |
| about 250° C. | at least 1.0 hours | about 100 MPa |
| about 250° C. | at least 1.0 hours | about 500 MPa |
| about 300° C. | at least 0.5 hours | about 1 kPa |
| about 300° C. | at least 0.5 hours | about 10 kPa |
| about 300° C. | at least 0.5 hours | about 100 kPa |
| about 300° C. | at least 0.5 hours | about 20 MPa |
| about 300° C. | at least 0.5 hours | about 100 MPa |
| about 300° C. | at least 0.5 hours | about 500 MPa |
| about 300° C. | at least 1.0 hours | about 1 kPa |
| about 300° C. | at least 1.0 hours | about 10 kPa |
| about 300° C. | at least 1.0 hours | about 100 kPa |
| about 300° C. | at least 1.0 hours | about 20 MPa |
| about 300° C. | at least 1.0 hours | about 100 MPa |
| about 300° C. | at least 1.0 hours | about 500 MPa |
| about 350° C. | at least 0.5 hours | about 1 kPa |
| about 350° C. | at least 0.5 hours | about 10 kPa |
| about 350° C. | at least 0.5 hours | about 100 kPa |
| about 350° C. | at least 0.5 hours | about 20 MPa |
| about 350° C. | at least 0.5 hours | about 100 MPa |
| about 350° C. | at least 0.5 hours | about 500 MPa |
| about 350° C. | at least 1.0 hours | about 1 kPa |
| about 350° C. | at least 1.0 hours | about 10 kPa |
| about 350° C. | at least 1.0 hours | about 100 kPa |
| about 350° C. | at least 1.0 hours | about 20 MPa |
| about 350° C. | at least 1.0 hours | about 100 MPa |
| about 350° C. | at least 1.0 hours | about 500 MPa |
| about 400° C. | at least 0.5 hours | about 1 kPa |
| about 400° C. | at least 0.5 hours | about 10 kPa |
| about 400° C. | at least 0.5 hours | about 100 kPa |
| about 400° C. | at least 0.5 hours | about 20 MPa |
| about 400° C. | at least 0.5 hours | about 100 MPa |
| about 400° C. | at least 0.5 hours | about 500 MPa |
| about 400° C. | at least 1.0 hours | about 1 kPa |
| about 400° C. | at least 1.0 hours | about 10 kPa |
| about 400° C. | at least 1.0 hours | about 100 kPa |
| about 400° C. | at least 1.0 hours | about 20 MPa |
| about 400° C. | at least 1.0 hours | about 100 MPa |
| about 400° C. | at least 1.0 hours | about 500 MPa |
| about 450° C. | at least 0.5 hours | about 1 kPa |
| about 450° C. | at least 0.5 hours | about 10 kPa |
| about 450° C. | at least 0.5 hours | about 100 kPa |
| about 450° C. | at least 0.5 hours | about 20 MPa |
| about 450° C. | at least 0.5 hours | about 100 MPa |
| about 450° C. | at least 0.5 hours | about 500 MPa |
| about 450° C. | at least 1.0 hours | about 1 kPa |
| about 450° C. | at least 1.0 hours | about 10 kPa |
| about 450° C. | at least 1.0 hours | about 100 kPa |
| about 450° C. | at least 1.0 hours | about 20 MPa |
| about 450° C. | at least 1.0 hours | about 100 MPa |
| about 450° C. | at least 1.0 hours | about 500 MPa |

The final cure of the coating compositions may allow the copper bond pad of the first semiconductor component copper interconnect to bond to the copper bond pad of the second semiconductor component copper interconnect, forming a copper-to-copper bond of the copper interconnects.

The final cure may cause bonds to form between the siloxane coating composition of the first semiconductor component second coating composition of the second semiconductor component, forming the bonding layer between the first and second semiconductor components. The siloxane coating may form bonds between the pre-cured siloxane coating composition and the second coating composition, such as a siloxane coating composition or a SiO₂ coating composition.

### V. Properties

At low temperatures, the siloxane coating composition can tack bond and is flexible. Conversely, at high temperatures the siloxane coating is rigid and holds the copper interconnects in place and forms the copper-to-copper bonds.

Further, the coating compositions and method of fusing the first semiconductor component and second semiconductor component to form a device allows for enhanced adhesion between the first and second semiconductor component. The pre-curing of the siloxane coating composition partially cures the siloxane coating while remaining flexible. When the first and second semiconductor components are contacted and finally cured, the bonding layer comprising the partially cured siloxane coating composition forms strong bonds at the high final curing temperatures to adhere the first and second semiconductor component together.

Further, by adding pressure (at least 1 MPa) to the device, the tack bonding of the siloxane coating composition is aided, forming a stronger adhesion of the first and second semiconductor component together during final cure.

### VI. Figures and Embodiments

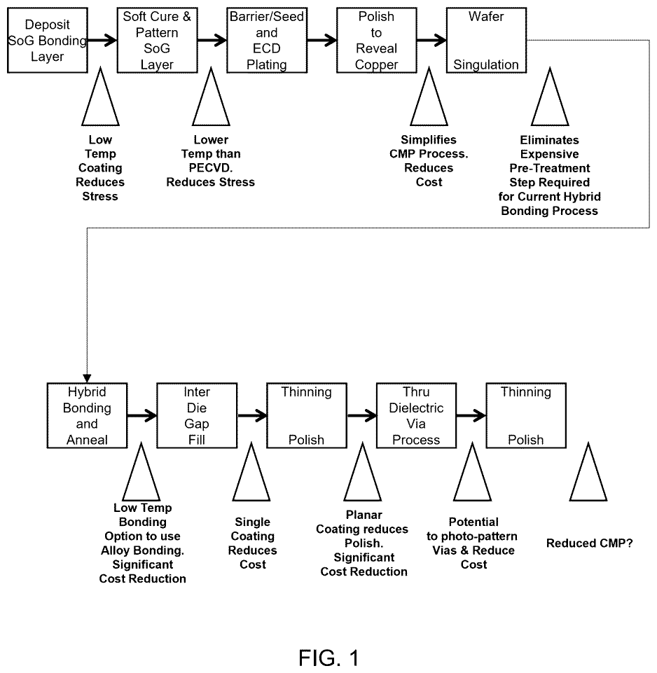

An exemplary process flow for the present disclosure is shown in FIG. 1, with key advantages over the PECVD oxide-based hybrid bonding prior art listed in each of several process steps.

### Novel Process Flows and Package Structures

New process methods are described herein, leading to significant reduction in process complexity, increase in process throughput, reduction in the number of process steps required to achieve ultra fine pitch Cu—Cu bonding, and elimination of certain high cost process steps such as plasma activation used in current Cu—Cu hybrid bonding processes. These process benefits are expected to result in substantial cost reduction over current Cu—Cu direct bonding process flows. The new structures described in this disclosure provide significant stress reduction during chip-on-wafer integration and during thermal cycling, improving product lifetimes and long term reliability. Several exemplary embodiments of the novel process flows and package structures described herein are not meant to be exhaustive, and various other methods and structures using the novel spin-on dielectric materials may be derived by someone skilled in the art.

### Process Flow #1: Spin-on Dielectric Drop in Replacement for PECVD Oxide

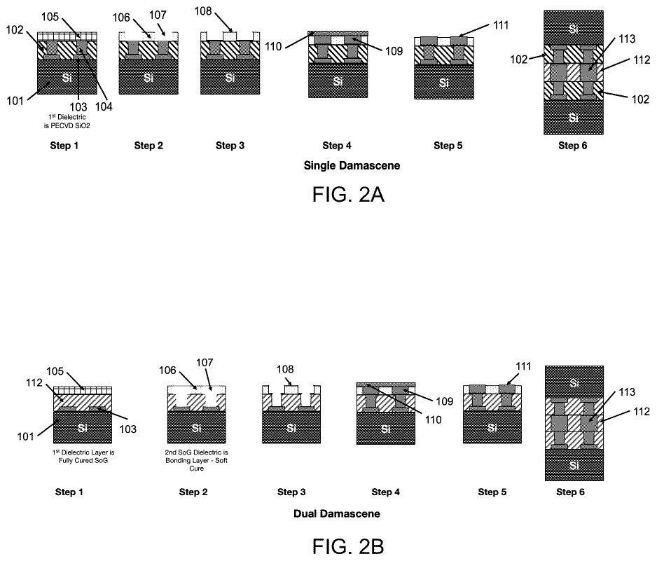

The complete process flow is shown in FIGS. 2A and 2B, wherein FIG. 2A is a Single Damascene process with ONE spin-on dielectric layer, and FIG. 2B is a Dual Damascene process with TWO spin-on dielectric layers-top surface as the bonding layer.

Step 1: Incoming wafer-Referring to FIGS. 2A and 2B, a silicon or non-silicon wafer or singulated chip 101, consisting of multiple front-end-of-line (FEOL), mid-end-of-line (MEOL) and back-end-of-line (BEOL) copper-dielectric layers, wherein the dielectrics are typical on-chip dielectrics such as porous silicon oxides, silicon nitrides, silicon oxi-nitrides and other inorganic materials. The first dielectric layer 102 is deposited either via PECVD oxide deposition (Single damascene flow) or a siloxane coating composition 112 (Dual damascene flow). In case of the Single damascene flow, the PECVD oxide dielectric 102 is patterned and metallized at this step. In case of the dual damascene flow, the siloxane coating composition 112 undergoes a dry pre-cure and full cure cycle at this step.

Step 2: Bonding layer patterning.—Still referring to FIGS. 2A and 2B, in the single damascene flow, FIG. 2A, the deposited and dry pre-cured spin-on dielectric layer 106 is patterned using an etch mask and a plasma reactive ion etch (RIE) process to form bonding pad openings 107. Alternate methods can include photolithographic patterning or laser ablation. In the dual damascene flow, FIG. 2B, two separate patterning steps are used to pattern via structures in the first siloxane coating composition 112, and bonding pad openings 107 in the second dielectric layer 106.

Steps 3-5: Copper Bonding Pad Metallization-Still referring to FIGS. 2A and 2B, a combination of steps 3, 4 and 5 are used to form copper bonding pad structures with typical dimensions in the single digit micron diameter or sub-micron diameter range on the first surface (top). The process flow in Step 3 consists of (a) deposition of a barrier layer (Tungsten, Titanium Nitride or other common diffusion barriers to prevent copper diffusion into the SiO₂ BEOL dielectric), (b) deposition of a thin copper seed layer, the barrier and seed layer stack represented by 108. The process in Step 4 consists of copper electroplating to fill the openings etched in the dielectric layer(s). For the single damascene flow, the copper filling 109 takes place in the bonding dielectric layer openings. For the Dual Damascene flow, FIG. 2B, the copper filling 109 takes place in structures etched into the bonding dielectric layer 106 and the first dielectric layer 102. In both the process flows, a thin copper “overburden” layer 110 is deposited across the top surface of the entire wafer. The final step in the metallization process involves chemical mechanical polishing (CMP) to remove the copper overburden layer 110, resulting in a nano-scale smooth surface with the copper pad 111 slightly protruding from the dielectric surface by a few nanometers to a few hundred nanometers in thickness.

Step 6: Two step bonding process-Still referring to FIGS. 2A and 2B, this disclosure describes for the first time a novel process involving a two-step bonding process, wherein, the first cure temperature (in Step 1) results in a partially cured film 106 of the as-deposited dielectric 105. Temperature ranges are described in further detail in the embodiments and exemplary data of this disclosure. The first partial cure retains the ability of the deposited dielectric to reflow and form a dielectric-to-dielectric bond, without the need for complex and costly high vacuum activation methods used in current SiO₂—SiO₂ hybrid bonding methods. The novel Cu—Cu bonding process flow described herein uses a second temperature bonding step bringing the two chips or wafer or chip-on-wafer in intimate contact with each other, first achieving a high strength dielectric-to-dielectric bond across the entire surface. A subsequent third temperature step is used to fully cure the novel dielectric formulations described in this disclosure. This third temperature step, achieved in the bonding tool, results in a conversion of the dielectric materials on both chips or wafers to a SiO₂-like mechanical property, resulting in equivalent ability to hold the copper pad structures in place with sub-micron alignment tolerance. The final and fourth temperature step inside the bonding tool results in copper-to-copper diffusion to complete the novel Cu—Cu and dielectric-dielectric bonding. The final structure consists of a fully cured siloxane coating composition 112 encapsulating ultra-fine pitch homogeneous copper interconnects 113.

### Process Flow #2: Optional Metal Bonding Layer

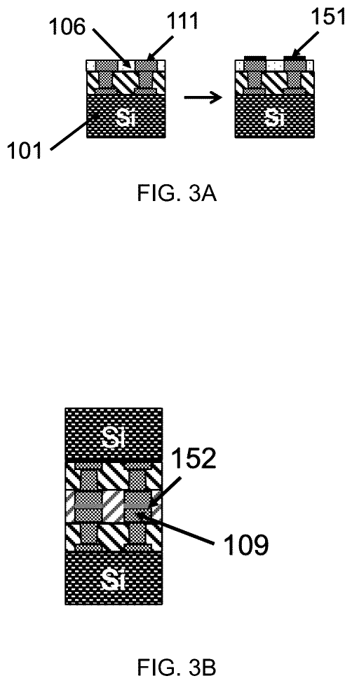

Optional Step in between Step 5 and Step 6 in Process Flow #1: To enable a lower bonding temperature for the Cu—Cu bonding, an optional step may be added to deposit and pattern a second metallic thin film 151 on the top surface of the copper bonding pads 111 as shown in FIG. 3A. The metallic layer can be chosen from a number of commonly used metals that alloy with copper to lower the melting point of copper. Exemplary metals include tin, silver, indium or other low melting point metals. The resulting final structure after bonding using this optional metallic interlayer consists of an intermetallic layer 152 in between the copper bonding pads 109, as shown in FIG. 3B.

### Process Flow #3: Optimized Process Flow for Spin-on Dielectric

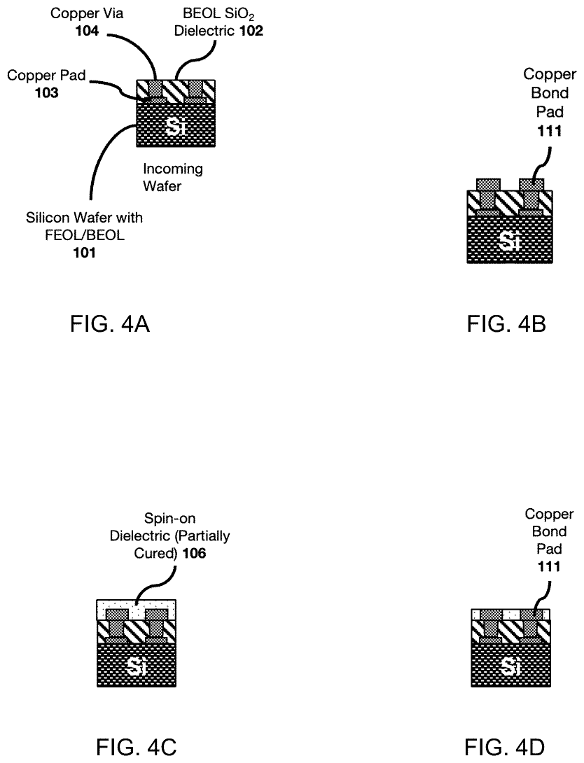

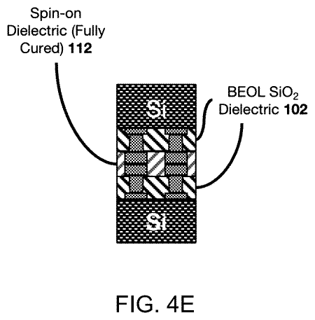

Step 1: Incoming wafer—As shown in FIG. 4A, a silicon or non-silicon wafer or singulated chip 101, consisting of multiple front-end-of-line (FEOL), mid-end-of-line (MEOL) and back-end-of-line (BEOL) copper-dielectric layers, wherein the dielectrics are typical on-chip dielectrics such as porous silicon oxides, silicon nitrides, silicon oxi-nitrides and other inorganic materials. Copper pads 103 and copper vias 104 embedded in the BEOL dielectric layer 102 form the structures under the bonding surface layers described in the subsequent steps below. The first surface (top) of the chip or wafer in this step has undergone chemical-mechanical polishing (CMP) to planarize the said surface and any post-CMP cleaning and drying steps in preparation for the chip-on-wafer or wafer-to-wafer bonding.

Step 2: Copper Bonding Pad formation—In this step, copper pad structures with typical dimensions in the single digit micron diameter or sub-micron diameter range are formed on the first surface (top) of step 1. The process flow in this steps consists of (a) deposition of a barrier layer (Tungsten, Titanium Nitride or other common diffusion barriers to prevent copper diffusion into the SiO₂ BEOL dielectric), (b) deposition of a thin copper seed layer, (c) deposition of a photoresist layer, (d) lithographic patterning of the photoresist layer, (e) copper electroplating to fill the openings in the photoresist layer to the desired copper pad thickness (typical 1-2 micrometers), (f) removal of the photoresist layer, (g) removal of the seed copper and barrier layers, and finally (h) post cleaning and drying steps, forming the copper bond pads 111, as shown in FIG. 4B.

Step 3: Bonding dielectric deposition—This step involves the deposition of one of the dielectric formulations described in this disclosure. Various methods of deposition can be used, the most common being spin-on methods widely used in wafer processing. Alternate deposition methods including but not limited to slot coating, slit coating, spray coating, curtain coating, screen printing, dry film lamination or other methods may be used to deposit the dielectric from liquid or paste or cast film formulations. The deposition step is followed by a dry pre-cure at a low temperature range of 20-200° C., preferably 25-150° C., and more preferably 80-120° C., to remove solvents from the deposited film 106, shown in FIG. 4C, and provide mechanical structure to the coating.

Step 4: Chemical-Mechanical Polish to reveal the copper bonding pads. The next step in the process flow involves chemical mechanical polishing (CMP) to remove the spin on dielectric layer 106, shown in FIG. 4C, covering the copper bonding pads 111, resulting in a nano-scale smooth surface with the copper pad 111 slightly protruding from the dielectric surface by a few nanometers to a few hundred nanometers in thickness, as shown in FIG. 4D.

Step 5: Two step bonding process. This disclosure describes for the first time a novel process involving a two-step bonding process, wherein, the first cure temperature (in Step 1) results in a film 106 of the as-deposited dielectric 105, as shown in FIGS. 2A and 2B. Temperature ranges are described in further detail in the embodiments and exemplary data supporting this disclosure. The first partial cure retains the ability of the deposited dielectric to reflow and form a dielectric-to-dielectric bond, without the need for complex and costly high vacuum activation methods used in current SiO₂—SiO₂ hybrid bonding methods. The novel Cu—Cu bonding process flow described herein uses a second temperature bonding step bringing the two chips or wafer or chip-on-wafer in intimate contact with each other, first achieving a high strength dielectric-to-dielectric bond across the entire surface. A subsequent third temperature step is used to fully cure the novel dielectric formulations described in this disclosure. This third temperature step, achieved in the bonding tool, results in a conversion of the dielectric materials on both chips or wafers to a SiO₂-like mechanical property, resulting in equivalent ability to hold the copper pad structures in place with sub-micron alignment tolerance. The final and fourth temperature step inside the bonding tool results in copper-to-copper diffusion to complete the novel Cu—Cu and dielectric-dielectric bonding. The final structure consists of a fully cured siloxane coating composition 112 encapsulating ultra-fine pitch homogeneous copper interconnects 113, as shown in FIGS. 2A, 2B, and 4E.

Process Flow #3B: Optimized Process Flow for Spin-on Dielectric with Spin on Dielectric as Underlying RDL Dielectric Layer

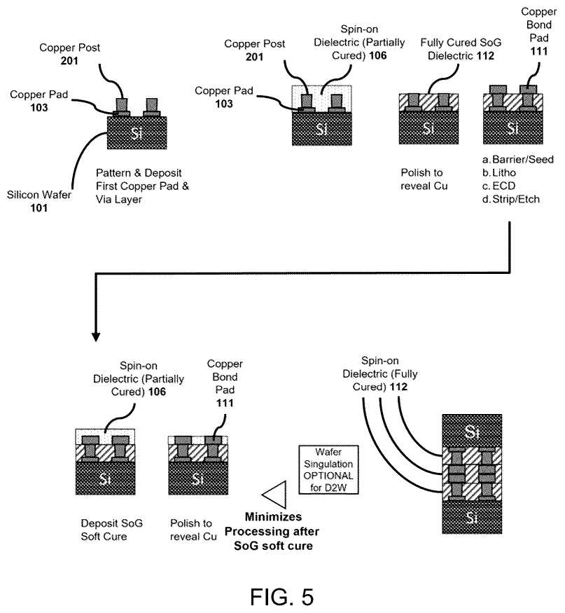

In another embodiment of the process flow #3, shown in FIG. 5, the first dielectric layer (under the bonding dielectric layer) can also be fabricated using the novel spin on dielectric formulations described in this disclosure. In this process flow, the first step involves patterning copper pads 103 and copper posts 201 on the incoming wafer surface with underlying FEOL, MEOL and BEOL interconnect layers. The second step is the deposition of the spin on dielectric and partially curing the dielectric film 106. A chemical-mechanical polish step is then applied to planarize the surface and reveal the copper posts 201, resulting in a nano-scale smooth surface. The process steps described in this process flow up to this step can also be used to form high density re-distribution layer (RDL) interconnects for 2.5D interposers, package substrates and other 3D interconnect substrates. The remaining process steps follow the same sequence of processes as process flow #3,resulting in structures with fully cured siloxane coating composition 112 encapsulating the copper posts 201 and Cu—Cu bonding pads 113, as shown in FIGS. 2A, 2B, and 5.

Process Flow #3C: Pad Formation Prior to Spin on Dielectric Deposition with Spin on Dielectric as Underlying Dielectric Layer with Optional Metal Bonding Layer to Lower Bonding Temperature

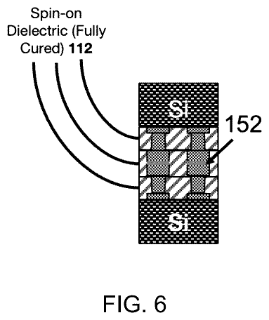

In another embodiment of process flow #3 optimized for the spin on dielectric material, a thin metal bonding layer can be introduced after the chemical mechanical polish step to prepare the surface for Cu—Cu bonding. Such a bonding metal layer reduces the final bonding temperature and results in an intermetallic layer 152 in between the copper bonding pads 111, as shown in FIGS. 5 and 6.

Process Flow #3D: Pad Formation Prior to Spin on Dielectric Deposition with Spin on Dielectric as Underlying Dielectric Layer PATTERNED by Damascene Process

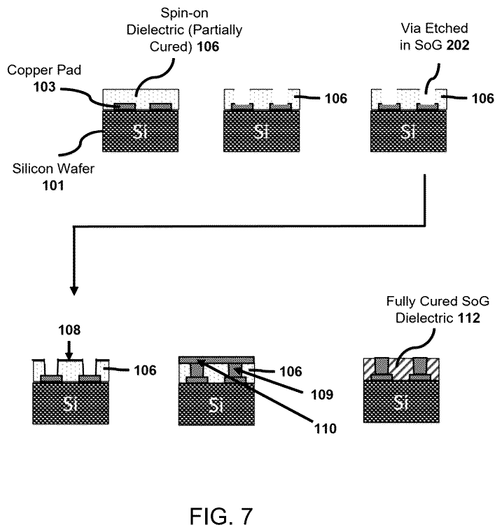

In this embodiment of process flow #3, shown in FIG. 7, spin on dielectric 106 is deposited and partially cured on the copper pads 103, followed by patterning to form via structures 202 by plasma etching or other methods described earlier. This is followed by deposition of barrier and seed metal layers 108, copper electroplating to fill the via structures 109, resulting in a copper overburden layer 110, and finally chemical mechanical polishing to form a planarized surface with fully cured siloxane coating composition 112 and revealed copper vias. The remaining process steps to complete the bonding pad formation in the bonding dielectric layer and hybrid bonding follow the same sequence and details described in process flow #3.

### EXAMPLES

Aspects of the present disclosure are further illustrated by reference to the following examples. It will be apparent to those skilled in the art that many modifications, both to materials, and methods, may be practiced without departing from the scope of the disclosure.

### Example 1: Air-Dried PSTR Film Bonding

A 20% PTSR-4 formulation, a siloxane coating composition (as described in the present disclosure) developed by Solstice Advanced Materials Inc., was filtered using a 0.1-micron filter for coating purposes. The filtered composition was applied to two four-inch silicon wafers through spin coating at a speed of 700 revolutions per minute (RPM). The wafers with the applied film were then air dried for 30 minutes in a hood to facilitate solvent evaporation. Subsequently, the air-dried films on the wafers were pressed together to form a sandwich structure, with the films positioned in the middle. This assembly was further cured in an ambient atmosphere at 250° C. for one hour, with a 1-kilogram weight applied on top. After the curing process, the sandwich was removed from the oven and allowed to cool to room temperature. The films adhered strongly and wafers could not be separated.

### Example 2: Low-Temperature Pre-Cured PSTR Film Bonding

A 20% PTSR-4 formulation, developed by Solstice Advanced Materials Inc., was filtered using a 0.1-micron filter for coating purposes. The filtered composition was applied to two four-inch silicon wafers through spin coating at a speed of 700 revolutions per minute (RPM). The wafers with the applied film were then baked on a hot plate set to a surface temperature of 70° C. for 30 seconds to facilitate solvent evaporation. The film thickness was measured using an ellipsometer, revealing a thickness of approximately 9456 Å after baking. Subsequently, the baked films on the wafers were pressed together to form a sandwich structure, with the films positioned in the middle. This assembly was further cured in an ambient atmosphere at 250° C. for one hour, with a 1-kilogram weight applied on top. After the curing process, the sandwich was removed from the oven and allowed to cool to room temperature. The films adhered strongly and wafers could not be separated.

### Example 3: Two-Step Pre-Cured PSTR Film Bonding

A 20% PTSR-4 formulation, developed by Solstice Advanced Materials Inc., was filtered using a 0.1-micron filter for coating purposes. The filtered composition was applied to two four-inch silicon wafers through spin coating at a speed of 700 revolutions per minute (RPM). The wafers with the applied film were baked sequentially on two hot plates: the first set to a surface temperature of 160° C. for one minute, followed by the second set to a surface temperature of 180° C. for an additional minute, to facilitate solvent evaporation. The film thickness was measured using an ellipsometer, revealing a thickness of approximately 8925 Å after baking. Subsequently, the baked films on the wafers were pressed together to form a sandwich structure, with the films positioned in the middle. This assembly was further cured in an ambient atmosphere at 400° C. for one hour, with a 1-kilogram weight applied on top. After the curing process, the sandwich was removed from the oven and allowed to cool to room temperature. The films adhered strongly and wafers could not be separated.

### Example 4: Three-Step Pre-Cured PSTR Film Bonding

A 20% PTSR-4 formulation, developed by Solstice Advanced Materials Inc., was filtered using a 0.1-micron filter for coating purposes. The filtered composition was applied to two four-inch silicon wafers through spin coating at a speed of 700 revolutions per minute (RPM). The wafers with the applied film were baked sequentially on three hot plates: initially on the first hot plate set to a surface temperature of 160° C. for one minute, followed by the second hot plate at 180° C. for an additional minute, and finally on the third hot plate at 250° C. for five minutes, to facilitate solvent evaporation. The film thickness was measured using an ellipsometer, revealing a thickness of approximately 7549 Å after baking. Subsequently, the baked films on the wafers were pressed together to form a sandwich structure, with the films positioned in the middle. This assembly was further cured in an ambient atmosphere at 400° C. for one hour, with a 1-kilogram weight applied on top. After the curing process, the sandwich was removed from the oven and allowed to cool to room temperature. The films adhered strongly and wafers could not be separated.

### Example 5: Three-Step Pre-Cured PSTR Film Bonding with Reduced Pressure

A 20% PTSR-4 formulation, developed by Solstice Advanced Materials Inc., was filtered using a 0.1-micron filter for coating purposes. The filtered composition was applied to two four-inch silicon wafers through spin coating at a speed of 700 revolutions per minute (RPM). The wafers with the applied film were baked sequentially on three hot plates: initially on the first hot plate set to a surface temperature of 160° C. for one minute, followed by the second hot plate at 180° C. for an additional minute, and finally on the third hot plate at 250° C. for five minutes, to facilitate solvent evaporation. The film thickness was measured using an ellipsometer, revealing a thickness of approximately 7549 Å after baking. Subsequently, the baked films on the wafers were pressed together to form a sandwich structure, with the films positioned in the middle. The assembly was further cured in an ambient atmosphere at 400° C. for one hour, with the 1-kilogram weight replaced by a 95-gram thick glass. After the curing process, the sandwich was removed from the oven and allowed to cool to room temperature. Upon separation, the films did not adhere well and could be easily separated.

### Example 6: Fully Cured PSTR Film Bonding with Reduced Pressure

A 20% PTSR-4 formulation, developed by Solstice Advanced Materials Inc., was filtered using a 0.1-micron filter for coating purposes. The filtered composition was applied to two four-inch silicon wafers through spin coating at a speed of 700 revolutions per minute (RPM). The wafers with the applied film were baked sequentially on two hot plates: the first set to a surface temperature of 160° C. for one minute, followed by the second set to a surface temperature of 180° C. for an additional minute, to facilitate solvent evaporation. The film thickness was measured using an ellipsometer, indicating a thickness of approximately 8440 Å after baking. Subsequently, the baked films were cured in an ambient atmosphere at 400° C. for one hour. The cured films on the wafers were then pressed together to form a sandwich structure, with the films positioned in the middle. This assembly was further cured in an ambient atmosphere at 400° C. for one hour, with the 1-kilogram weight replaced by a 95-gram thick glass. After the curing process, the sandwich was removed from the oven and allowed to cool to room temperature. Upon separation, the films did not adhere well and could be easily separated.

### Example 7: Fully Cured PSTR Film Bonding

A 20% PTSR-4 formulation, developed by Solstice Advanced Materials Inc., was filtered using a 0.1-micron filter for coating purposes. The filtered composition was applied to two four-inch silicon wafers through spin coating at a speed of 700 revolutions per minute (RPM). The wafers with the applied film were baked sequentially on two hot plates: the first set to a surface temperature of 160° C. for one minute, followed by the second set to a surface temperature of 180° C. for an additional minute, to facilitate solvent evaporation. Subsequently, the baked films were cured in an ambient atmosphere at 400° C. for one hour. The cured films on the wafers were then pressed together to form a sandwich structure, with the films positioned in the middle. This assembly was further cured in an ambient atmosphere at 400° C. for one hour, with a 1-kilogram weight applied on top. After the curing process, the sandwich was removed from the oven and allowed to cool to room temperature. Upon separation, the films did not adhere well and could be easily separated.

### Example 8: CVD SiO₂ Film Bonding

Eight-inch wafers were deposited with a 6910 A thick SiO₂ film on the AMAT P5000 using a CVD process with SiH₄. The two wafers were pressed together to form a sandwich structure, with the films positioned in the middle. A 1-kilogram weight was placed on top of the sandwich structure, and this assembly was then cured at 400° C. for one hour. After the curing process, the sandwich was removed from the oven and allowed to cool to room temperature. Upon separation, the films did not adhere well and could be easily separated.

### Example 9: CVD SiO₂ Film Bonding with Fluorocarbon Plasma Treatment

Eight-inch wafers were deposited with a 6910 A thick SiO₂ film on the AMAT P5000 using a CVD process with SiH₄. The films were then exposed to fluorocarbon gases under plasma for one minute. The film thickness was measured using an ellipsometer, revealing a thickness of approximately 3505 Å after plasma exposure. Subsequently, the two wafers were pressed together to form a sandwich structure, with the films positioned in the middle. A 1-kilogram weight was placed on top of the sandwich structure, and this assembly was then cured at 400° C. for one hour. After the curing process, the sandwich was removed from the oven and allowed to cool to room temperature. Upon separation, the films did not adhere well and could be easily separated.

### Example 10: CVD SiO₂ Film Bonding with Oxygen Plasma Treatment

Eight-inch wafers were deposited with a 6910 A thick SiO₂ film on the AMAT P5000 using a CVD process with SiH₄. The films were then exposed to O₂ under plasma for one minute. The film thickness was measured using an ellipsometer, revealing a thickness of approximately 6656 Å after plasma exposure. Subsequently, the two wafers were pressed together to form a sandwich structure, with the films positioned in the middle. A 1-kilogram weight was placed on top of the sandwich structure, and this assembly was then cured at 400° C. for one hour. After the curing process, the sandwich was removed from the oven and allowed to cool to room temperature. Upon separation, the films did not adhere well and could be easily separated.

### Example 11: Two-Step Pre-Cured PSTR to CVD SiO₂ Bonding

A 20% PTSR-4 formulation, developed by Solstice Advanced Materials Inc., was filtered using a 0.1-micron filter for coating purposes. The filtered composition was applied to an eight-inch silicon wafer through spin coating at a speed of 700 revolutions per minute (RPM). The wafer with the applied film was baked sequentially on two hot plates: the first set to a surface temperature of 160° C. for one minute, followed by the second set to a surface temperature of 180° C. for an additional minute, to facilitate solvent evaporation. The polymer coated wafer, and another eight-inch wafer coated with 6910A thick SiO₂ film, which was deposited by CVD process using SiH₄, were then pressed together to form a sandwich structure, with the films positioned in the middle. A 1-kilogram weight was placed on top of the sandwich structure and this assembly was then cured at 400° C. for one hour. After the curing process, the sandwich was removed from the oven and allowed to cool to room temperature. Upon separation, the polymer film adhered strongly to the CVD Oxide film and wafers could not be separated.

### Example 12: Three-Step Pre-Cured PSTR to CVD SiO₂ Bonding

A 20% PTSR-4 formulation, developed by Solstice Advanced Materials Inc., was filtered using a 0.1-micron filter for coating purposes. The filtered composition was applied to an eight-inch silicon wafer through spin coating at a speed of 700 revolutions per minute (RPM). The wafers with the applied film were baked sequentially on three hot plates: initially on the first hot plate set to a surface temperature of 160° C. for one minute, followed by the second hot plate at 180° C. for an additional minute, and finally on the third hot plate at 250° C. for five minutes, to facilitate solvent evaporation. The polymer coated wafer, and another eight-inch wafer coated with 6910A thick SiO₂ film, which was deposited by CVD process using SiH₄, were then pressed together to form a sandwich structure, with the films positioned in the middle. A 1-kilogram weight was placed on top of the sandwich structure and this assembly was then cured at 400° C. for one hour. After the curing process, the sandwich was removed from the oven and allowed to cool to room temperature. Upon separation, the polymer film adhered strongly to the CVD Oxide film and wafers could not be separated.

### Example 13: Fully Cured PSTR to CVD SiO₂ Bonding

A 20% PTSR-4 formulation, developed by Solstice Advanced Materials Inc., was filtered using a 0.1-micron filter for coating purposes. The filtered composition was applied to an eight-inch silicon wafer through spin coating at a speed of 700 revolutions per minute (RPM). The wafer with the applied film was baked sequentially on two hot plates: the first set to a surface temperature of 160° C. for one minute, followed by the second set to a surface temperature of 180° C. for an additional minute, to facilitate solvent evaporation. Subsequently, the baked films were cured in an ambient atmosphere at 400° C. for one hour. The polymer coated wafer, and another eight-inch wafer coated with 6910A thick SiO₂ film, which was deposited by CVD process using SiH₄, were then pressed together to form a sandwich structure, with the films positioned in the middle. A 1-kilogram weight was placed on top of the sandwich structure and this assembly was then cured at 400° C. for one hour. After the curing process, the sandwich was removed from the oven and allowed to cool to room temperature. Upon separation, the films did not adhere well and could be easily separated.

### Example 14: Fully Cured and CMP'd PTSR with BAR6610R Slurry, Followed by Manual C-Clamp Bonding

A 35% PTSR-7 formulation, a siloxane coating composition (as described in the present disclosure) developed by Solstice Advanced Materials Inc., was filtered using a 0.1-micron filter for coating purposes. The filtered composition was applied to an eight-inch silicon wafer through spin coating at a speed of 1000 revolutions per minute (RPM). The wafer with the applied film was then baked sequentially for one minute at 160° C., one minute at 180° C., one minute at 210° C., and one hour at 350° C. After cure, film thickness was measured with a Nanometrics ellipsometer. The cured film was then CMP'd using a soft polyurethane pad and Versum Materials BAR6610R, a silica and peroxide slurry with a pH of 9.3. The film was subjected to two CMP steps of 2 min and 4 min duration, each with a downforce pressure of 1.5 psi. After each CMP step, the wafer was cleaned with PVA brushes and a surfactant cleaning chemistry with a pH of 3.2. After CMP, wafer defectivity was characterized using a Tencor SurfScan SP1 defect analysis system, and film thickness was measured with a Nova SemDex 301 spectroscopic reflectometer. Finally, a diamond cutter was used to cut out two 1 cm×1 cm coupons of this wafer by hand. The two coupons were pressed together using a C-clamp, tightened by hand to apply approximately 800-1500N of force, and heated at 350° C. for 1 hour. The applied force was estimated by manually clamping a Haas clamp force gauge in the same clamp used for bonding using a similar level of effort as was applied in the bonding test. After heating under pressure, it was qualitatively observed that the wafers stuck strongly together. It was difficult but possible to pull the wafers apart by hand; however, the coating was visibly rough and fractured after doing so.

### Example 15: Fully Cured and CMP'd PTSR with Acuplane 5110 Slurry, Low Pressure, and Long CMP Duration, Followed by Manual C-Clamp Bonding

A 35% PTSR-7 formulation, developed by Solstice Advanced Materials Inc., was filtered using a 0.1-micron filter for coating purposes. The filtered composition was applied to an eight-inch silicon wafer through spin coating at a speed of 1000 revolutions per minute (RPM). The wafer with the applied film was then baked sequentially for one minute at 160° C., one minute at 180° C., one minute at 210° C., and one hour at 350° C. After cure, film thickness was measured with a Nanometrics ellipsometer. The cured film was then CMP'd using a soft polyurethane pad and DuPont Acuplane 5110, a silica and peroxide slurry with a pH of 9.8, for 10 minutes under 1.5 psi of pressure. Following CMP, the wafer was cleaned with PVA brushes and a surfactant cleaning chemistry with a pH of 3.2. Wafer defectivity was characterized using a Tencor SurfScan SP1 defect analysis system, and film thickness was measured with a Nova SemDex 301 spectroscopic reflectometer. Finally, a diamond cutter was used to cut out two 1 cm×1 cm coupons of this wafer by hand. The two coupons were pressed together using a C-clamp, tightened by hand to apply approximately 800-1500N of force, and heated at 350° C. for 1 hour. The applied force was estimated by manually clamping a Haas clamp force gauge in the same clamp used for bonding using a similar level of effort as was applied in the bonding test. After heating under pressure, it was qualitatively observed that the wafers stuck strongly together. It was difficult but possible to pull the wafers apart by hand; however, the coating was visibly rough and fractured after doing so.

### Example 16: Fully Cured and CMP'd PTSR with Acuplane 5110 Slurry, High Pressure, and Short CMP Duration, Followed by Manual C-Clamp Bonding

A 35% PTSR-7 formulation, developed by Solstice Advanced Materials Inc., was filtered using a 0.1-micron filter for coating purposes. The filtered composition was applied to an eight-inch silicon wafer through spin coating at a speed of 1000 revolutions per minute (RPM). The wafer with the applied film was then baked sequentially for one minute at 160° C., one minute at 180° C., one minute at 210° C., and one hour at 350° C. After cure, film thickness was measured with a Nanometrics ellipsometer. The cured film was then CMP'd using a soft polyurethane pad and DuPont Acuplane 5110, a silica and peroxide slurry with a pH of 9.8, for two minutes under 3.0 psi of pressure. Following CMP, the wafer was cleaned with PVA brushes and a surfactant cleaning chemistry with a pH of 3.2. Wafer defectivity was characterized using a Tencor SurfScan SP1 defect analysis system, and film thickness was measured with a Nova SemDex 301 spectroscopic reflectometer. Finally, a diamond cutter was used to cut out two 1 cm×1 cm coupons of this wafer by hand. The two coupons were pressed together using a C-clamp, tightened by hand to apply approximately 800-1500N of force, and heated at 350° C. for 1 hour. The applied force was estimated by manually clamping a Haas clamp force gauge in the same clamp used for bonding using a similar level of effort as was applied in the bonding test. After heating under pressure, it was qualitatively observed that the wafers stuck strongly together. It was difficult but possible to pull the wafers apart by hand; however, the coating was visibly rough and fractured after doing so.

### Example 17: Fully Cured and CMP'd PTSR with Acuplane 5110 Slurry, Low Pressure, and Short CMP Duration, Followed by Manual C-Clamp Bonding

A 35% PTSR-7 formulation, developed by Solstice Advanced Materials Inc., was filtered using a 0.1-micron filter for coating purposes. The filtered composition was applied to an eight-inch silicon wafer through spin coating at a speed of 1000 revolutions per minute (RPM). The wafer with the applied film was then baked sequentially for one minute at 160° C., one minute at 180° C., one minute at 210° C., and one hour at 350° C. After cure, film thickness was measured with a Nanometrics ellipsometer. The cured film was then CMP'd using a soft polyurethane pad and DuPont Acuplane 5110, a silica and peroxide slurry with a pH of 9.8, for two minutes under 1.5 psi of pressure. Following CMP, the wafer was cleaned with PVA brushes and a surfactant cleaning chemistry with a pH of 3.2. Wafer defectivity was characterized using a Tencor SurfScan SP1 defect analysis system, and film thickness was measured with a Nova SemDex 301 spectroscopic reflectometer. Finally, a diamond cutter was used to cut out two 1 cm×1 cm coupons of this wafer by hand. The two coupons were pressed together using a C-clamp, tightened by hand to apply approximately 800-1500N of force, and heated at 350° C. for 1 hour. The applied force was estimated by manually clamping a Haas clamp force gauge in the same clamp used for bonding using a similar level of effort as was applied in the bonding test. After heating under pressure, it was qualitatively observed that the wafers stuck strongly together. It was difficult but possible to pull the wafers apart by hand; however, the coating was visibly rough and fractured after doing so.

### Example 18: Fully Cured and CMP'd PTSR with Acuplane 5110 Slurry, High Pressure, and Short CMP Duration, Followed by Torque Wrench C-Clamp Bonding

A 35% PTSR-7 formulation, developed by Solstice Advanced Materials Inc., was filtered using a 0.1-micron filter for coating purposes. The filtered composition was applied to an eight-inch silicon wafer through spin coating at a speed of 1000 revolutions per minute (RPM). The wafer with the applied film was then baked sequentially for one minute at 160° C., one minute at 180° C., one minute at 210° C., and one hour at 350° C. After cure, film thickness was measured with a Nanometrics ellipsometer. The cured film was then CMP'd using a soft polyurethane pad and DuPont Acuplane 5110, a silica and peroxide slurry with a pH of 9.8, for two minutes under 3.0 psi of pressure. Following CMP, the wafer was cleaned with PVA brushes and a surfactant cleaning chemistry with a pH of 3.2. Wafer defectivity was characterized using a Tencor SurfScan SP1 defect analysis system, and film thickness was measured with a Nova SemDex 301 spectroscopic reflectometer. Water contact angle post-CMP was measured by imaging five sessile drops of water on the surface of the wafer using an AST Products VCA3000S video contact angle system. The water contact angle was measured independently for each drop, and the reported value is the average across all five drops. Finally, a diamond cutter was used to cut out two 1.4″×1.5″ coupons of this wafer by hand. The two coupons were pressed together under about 800 lbs of force using a C-clamp tightened with a torque wrench. The pad on the C-clamp was 0.75″ in diameter. The force applied by the clamp was measured by using the same torque setting on the wrench (120 lb*in) to clamp a Haas clamp force gauge. To protect the wafers from cracking under uneven pressure applied by the clamp, the wafers were sandwiched between two 2″×2″ 11 gauge steel plates. The clamped wafers were then heated at 350° C. for 1 hour. After heating under pressure, it was qualitatively observed that the wafers stuck strongly together. It was difficult but possible to pull the wafers apart by hand; however, the coating was visibly rough and fractured across the majority of the coupon after doing so.

### Example 19: Fully Cured and CMP'd PTSR with Acuplane 5110 Slurry, Low Pressure, and Short CMP Duration, Torque Wrench C-Clamp Bonding

A 35% PTSR-7 formulation, developed by Solstice Advanced Materials Inc., was filtered using a 0.1-micron filter for coating purposes. The filtered composition was applied to an eight-inch silicon wafer through spin coating at a speed of 1000 revolutions per minute (RPM). The wafer with the applied film was then baked sequentially for one minute at 160° C., one minute at 180° C., one minute at 210° C., and one hour at 350° C. After cure, film thickness was measured with a Nanometrics ellipsometer. The cured film was then CMP'd using a soft polyurethane pad and DuPont Acuplane 5110, a silica and peroxide slurry with a pH of 9.8, for two minutes under 1.5 psi of pressure. Following CMP, the wafer was cleaned with PVA brushes and a surfactant cleaning chemistry with a pH of 3.2. Wafer defectivity was characterized using a Tencor SurfScan SP1 defect analysis system, and film thickness was measured with a Nova SemDex 301 spectroscopic reflectometer. Water contact angle post-CMP was measured by imaging five sessile drops of water on the surface of the wafer using an AST Products VCA3000S video contact angle system. The water contact angle was measured independently for each drop, and the reported value is the average across all five drops. Finally, a diamond cutter was used to cut out two 1.4″×1.5″ coupons of this wafer by hand. The two coupons were pressed together under about 800 lbs of force using a C-clamp tightened with a torque wrench. The pad on the C-clamp was 0.75″ in diameter. The force applied by the clamp was measured by using the same torque setting on the wrench (120 lb*in) to clamp a Haas clamp force gauge. To protect the wafers from cracking under uneven pressure applied by the clamp, the wafers were sandwiched between two 2″×2″ 11 gauge steel plates. The clamped wafers were then heated at 350° C. for 1 hour. After heating under pressure, it was qualitatively observed that the wafers stuck strongly together. It was difficult but possible to pull the wafers apart by hand; however, the coating was visibly rough and fractured across the majority of the coupon after doing so.

### Example 20: Fully Cured, Non-CMP'd PTSR-4, Torque Wrench C-Clamp Bonding

A 20% PTSR-4 formulation, developed by Solstice Advanced Materials Inc., was filtered using a 0.1-micron filter for coating purposes. The filtered composition was applied to an eight-inch silicon wafer through spin coating at a speed of 1000 revolutions per minute (RPM). The wafer with the applied film was then baked sequentially for one minute at 140° C., one minute at 180° C., one minute at 210° C., and one hour at 350° C. After cure, film thickness was measured with a Nanometrics ellipsometer. Water contact angle post-CMP was measured by imaging five sessile drops of water on the surface of the wafer using an AST Products VCA3000S video contact angle system. The water contact angle was measured independently for each drop, and the reported value is the average across all five drops. A diamond cutter was used to cut out two 1.4″×1.5″ coupons of this wafer by hand. The two coupons were pressed together under about 800 lbs of force using a C-clamp tightened with a torque wrench. The pad on the C-clamp was 0.75″ in diameter. The force applied by the clamp was measured by using the same torque setting on the wrench (120 lb*in) to clamp a Haas clamp force gauge. To protect the wafers from cracking under uneven pressure applied by the clamp, the wafers were sandwiched between two 2″×2″ 11 gauge steel plates. The clamped wafers were then heated at 350° C. for 1 hour. After heating under pressure, it was qualitatively observed that the wafers did not stick together well. It was easy to pull the wafers apart by hand, and the coating was smooth and undamaged after doing so.

### Example 21: Fully Cured, Non-CMP'd PTSR-4 Mixed with P (GLYMO). Torque Wrench C-Clamp Bonding

A 20% PTSR-4 formulation, developed by Solstice Advanced Materials Inc., and a 20% solution of poly(glycidoxypropyltrimethoxysilane), abbreviated as P (GLYMO), developed by Solstice Advanced Materials Inc., were mixed in 1:1 proportions by mass and filtered using a 0.1-micron filter for coating purposes. The filtered composition was applied to an eight-inch silicon wafer through spin coating at a speed of 1000 revolutions per minute (RPM). The wafer with the applied film was then baked sequentially for one minute at 140° C., one minute at 180° C., one minute at 210° C., and one hour at 350° C. After cure, film thickness was measured with a Nanometrics ellipsometer. Water contact angle post-CMP was measured by imaging five sessile drops of water on the surface of the wafer using an AST Products VCA3000S video contact angle system. The water contact angle was measured independently for each drop, and the reported value is the average across all five drops. A diamond cutter was used to cut out two 1.4″×1.5″ coupons of this wafer by hand. The two coupons were pressed together under about 800 lbs of force using a C-clamp tightened with a torque wrench. The pad on the C-clamp was 0.75″ in diameter. The force applied by the clamp was measured by using the same torque setting on the wrench (120 lb*in) to clamp a Haas clamp force gauge. To protect the wafers from cracking under uneven pressure applied by the clamp, the wafers were sandwiched between two 2″×2″ 11 gauge steel plates. The clamped wafers were then heated at 350° C. for 1 hour. After heating under pressure, it was qualitatively observed that the wafers stuck together moderately well. It was moderately difficult to pull the wafers apart by hand, and the coating was mostly smooth and undamaged after doing so; however, the portion of the coating near where the pad of the c-clamp had been was visibly rough and fractured.

A summary of the adhesion testing results for each of the Examples above are shown in Tables 1-5, below. The pre-curing conditions, post-bonding conditions, and pressure applied to the coated wafers to test adhesion are also noted in the tables. Table 4 also includes the CMP process conditions, post-CMP wafer defect counts, and post-CMP film thickness decrease. Table 5 also includes the film thickness, water contact angle, and composition of each sample.

TABLE 1
Adhesion Tests for Examples 1-7 (Bonding Between Two Polymer Spin-
Coated Wafers)

| | Spin on | | | | | |
|---|---|---|---|---|---|---|
| | siloxane | | | Pressure | FT(A) | |
| Example | material | Pre-Curing | Post-Bonding | (Weight) | Pre-curing | Adhesion |
| 1 | PTSR | Air dry 30 min | 250 °C 1 hr | 1 kg | | Yes |
| 2 | PTSR | 70 °C 30 s | 250 °C 1 hr | 1 kg | 9456 | Yes |
| 3 | PTSR | 160/180 °C | 400 °C 1 hr | 1 kg | 8925 | Yes |
| | | 1 min | | | | |
| 4 | PTSR | 160/180 °C | 400 °C 1 hr | 1 kg | 7549 | Yes |
| | | 1 min | | | | |
| | | 250 °C 5 min | | | | |
| 5 | PTSR | 160/180 °C | 400 °C 1 hr | 95 gm | 7549 | No |
| | | 1 min | | | | |
| | | 250 °C 5 min | | | | |
| 6 | PTSR | 160/180 °C | 400 °C 1 hr | 95 gm | 8440 | No |
| | | 1 min | | | | |
| | | 400 °C 60 min | | | | |
| 7 | PTSR | 160/180 °C | 400 °C 1 hr | 1 kg | 8440 | No |
| | | 1 min | | | | |
| | | 400 °C 60 min | | | | |

TABLE 2
Adhesion Tests for Examples 8-10 (Bonding Between Two
CVD SiO₂-Coated Wafers)

| | Spin on | | | | | |
|---|---|---|---|---|---|---|
| | siloxane | | | Pressure | FT(A) | |
| Example | material | Pre-Curing | Post-Bonding | (Weight) | Pre-curing | Adhesion |
| 8 | CVD SiO₂ | — | 400 °C 1 hr | 1 kg | 6910 | No |
| 9 | CVD SiO₂ + | — | 400 °C 1 hr | 1 kg | 3505 | No |
| | CFx Plasma | | | | | |
| 10 | CVD SiO₂ + | — | 400 °C 1 hr | 1 kg | 6656 | No |
| | O₂ Plasma | | | | | |

TABLE 3
Adhesion Tests for Examples 11-13 (Bonding Between One Polymer
Spin-Coated Wafer and One CVD-SiO₂ Coated Wafer)

| | Spin on | | | | | |
|---|---|---|---|---|---|---|
| | siloxane | | Post- | Pressure | FT(A) Pre- | |
| Example | material | Pre-Curing | Bonding | (Weight) | curing | Adhesion |
| 11 | PTSR | 160/180 °C 1 min | 400 °C 1 hr | 1 kg | 8742 | Yes |
| 12 | PTSR | 160/180 °C 1 min | 400 °C 1 hr | 1 kg | 7635 | Yes |
| | | 250 °C 5 min | | | | |
| 13 | PTSR | 160/180 °C 1 min | 400 °C 1 hr | 1 kg | 8101 | No |
| | | 400 °C 60 min | | | | |

TABLE 4
Adhesion Tests for Examples 14-17 (Manually Tightened Bonding
Between Polymer-Coated and CMP'd Wafers)

| | CMP | CMP | CMP | Post-CMP Point | FT removed | |
|---|---|---|---|---|---|---|
| Example | Slurry | Duration | pressure | Defects, 0.2-2 um | (nm) | Adhesion |
| 14 | BAR6610R | 2 min + 4 | 1.5 psi | 17394 | 145.4 | Yes |
| | | min | | | | |
| 15 | Acuplane | 10 min | 1.5 psi | 4173 | 45.8 | Yes |
| | 5110 | | | | | |
| 16 | Acuplane | 2 min | 3.0 psi | 3835 | 40.9 | Yes |
| | 5110 | | | | | |
| 17 | Acuplane | 2 min | 1.5 psi | 5993 | 9.5 | Yes |
| | 5110 | | | | | |

In Table 4, all wafers were coated with PTSR-7 and baked at 160° C./1 min+180° C./1 min+210° C./1 min+350° C./1 hour. The film thickness before CMP was about 2 μm for all wafers. The bonding step took place at 350° C./1 hour for all wafers with applied pressure between 8-15 MPa. Because pressure was applied by manually tightening a c-clamp, it was not possible to precisely measure the applied pressure for each wafer.

TABLE 5
Adhesion Tests for Examples 18-21 (Torque-Wrench Tightened Bonding
Between Polymer-Coated Wafers)

| | | Film | | | | |
|---|---|---|---|---|---|---|
| | | Thickness | CMP | FT removed | Water Contact | |
| Example | Composition | (A) | Pressure | (nm) | Angle (deg) | Adhesion |
| 18 | PTSR-7 | 2000 nm | 3.0 psi | 40.9 | 68 | Strong |
| 19 | PTSR-7 | 2000 nm | 1.5 psi | 9.5 | 74 | Strong |
| 20 | PTSR-4 | 700 nm | N/A | N/A | 94 | None |
| 21 | 50% PTSR- | 700 nm | N/A | N/A | 63 | Moderate |
| | 4/50% | | | | | |
| | P(GLYMO) | | | | | |

In Table 5, all wafers were coated with PTSR-7 and baked at 140 C/1 min (Examples 20+21) or 160° C./1 min (Examples 18+19)+180° C./1 min+210° C./1 min+350° C./1 hour. The bonding step took place at 350° C./1 hour for all wafers with applied pressure between 3-12 MPa. Although it was possible to more accurately measure the applied force using a force gauge, the pressure distribution was not uniform over the coupon. Rather, it was higher near the pad of the c-clamp and lower outside of that area. This was evident because the wafer in Example 21 was bonded only in the area under and near the pad of the c-clamp. However, because the clamps were tightened with a fixed torque, there is confidence that Examples 18-21 were all subject to the same pressure distribution, which is not necessarily the case for examples 14-17, which were tightened by hand.

### Discussion of Adhesion of Polymer Spin-Coated Wafers

Examples 1~4 showed good adhesion between the wafers. Examples 1~4 had suitable conditions during pre-curing and a suitable weight added during final curing to allow form a bonding layer between the siloxane coating compositions on the first and second wafers to adhere. Examples 1~4 demonstrate the importance of preserving bonding ability of the films by minimizing crosslinking during the pre-cure stage.

Examples 5-7 did not adhere. The wafers in Example 5 were not pressed together during curing with enough weight to cause adhesion. Example 5 may be compared to Example 4 and illustrates the need for the application of adequate force to affect the bonding at pre-curing temperatures where a film's bonding ability can be compromised due to onset of crosslinking.

Examples 6 and 7 were baked at too high of a temperature for too long, causing the coatings on each wafer to be fully cured prior to combination of the wafers. The fully cured coated wafers could not adhere due to lack of further bonding between partially cured coatings during curing. Since both Example 6 and Example 7 did not adhere, it can be concluded that the addition of further weight during final cure does not overcome the benefit of suitable pre-curing of the coated wafers.

### Discussion of Adhesion of CVD SiO₂ Coated Wafers

Examples 8-10 did not adhere. Example 8 used CVD oxide as the bonding layer and the lack of adhesion may be due to application method, heat and pressure not being adequate to affect bonding. The film produced by CVD methods itself may be inherently unreactive and unable to form a bond due to the lack of presence of surface reactive species.

Examples 9 and 10 verifies that the surface activation of CVD layers via exposure to plasma to generate surface hydroxyls and renders the substrate surface more hydrophilic and promotes bonding. Lack of adhesion in these examples suggests that perhaps more exotic means to activate surfaces of CVD oxide layers would be required.

### Discussion of Adhesion of One Polymer Spin-Coated Wafer to One CVD SiO₂ Coated Wafer

Examples 11 and 12 had good adhesion. Both Examples 11 and 12 included baking the polymer spin-on coated wafer at a temperature no hotter than 2500C and for no longer than 7 min total. Further, both Examples 11 and 12 had 1 kg of weight applied during adhesion and final curing. The semi-cured spin-on siloxane coating was able to adhere to the SiO₂ coating of the second wafer during final cure.

Conversely, Example 13 did not adhere. The spin-on siloxane coating was pre-cured at a temperature high enough to cure the coating enough that the two wafers could not bond and adhere to each other, despite the 1 kg weight added to the wafers during adhesion and final cure. Therefore, the test results show that the semi-cured PTSR coating provides the ability for the wafers to adhere to each other.

Discussion of Adhesion of CMP'd and Non-CMP'd Wafers Under High Pressure Applied by a C-Clamp.

Examples 14-19 all showed good adhesion, indicating that cured and CMP'd PTSR can be bonded after thermocompression bonding at 350 C for 1 hour under a pressure of at least 3 MPa. The type of slurry used, duration, downward pressure, or total amount of material removed during CMP did not affect adhesion, qualitatively. Defects counts were higher than one would target in this application. In a prophetic example, the CMP process, particularly the post-CMP cleaning step, would be improved to better remove particle defects. Fewer defects on the surface could further enhance adhesion between CMP'd wafers.

However, Example 20 shows that cured and non-CMP'd PTSR does not bond under the same conditions. Examples 14-20 also show that the water contact angle of PTSR decreases from 94 degrees before CMP to 68-74 degrees after CMP. This is possibly due to additional silanol groups exposed by the chemistry of the CMP slurry. Example 21 shows a non-CMP'd film with lower water contact angle of 63 degrees achieved by adding more hydrophilic functional groups. This film showed better adhesion than the non-CMP'd film in Example 20, but worse adhesion than the CMP'd films in Examples 18-19. This confirms that greater hydrophilicity can drive stronger adhesion, but also highlights the importance of CMP in the process flow. The ability of CMP to improve adhesion is due to more than just the increased hydrophilicity and may indicate the importance of creating a smooth, planar surface for bonding.

Wherein particular examples of this disclosure have been described above for purposes of illustration, it will be evident to those skilled in the art that numerous variations of the details of the present disclosure may be made without departing from the disclosure as defined in the appended claims. This application is therefore intended to cover any variations, uses, or adaptations of the disclosure using its general principles. Further, this application is intended to cover such departures from the present disclosure as come within known or customary practice in the art to which this disclosure pertains and which fall within the limits of the appended claims.

### Example 22: Hybrid Bonding

In one example of Process Flow #3, two patterned silicon wafer with exposed copper pads are coated with a spin-on dielectric such as Solstice PTSR or any similar material. The spin-coating process includes spinning the semiconductor component at a speed of about 500 rpm to about 1100 rpm. The subsequent bake steps may include pre-curing the siloxane coating composition by exposing it to a temperature from about 40° C. to about 100° C. for about 10 to about 60 seconds; or exposing it to room temperature (about 20-25° C.) for about 10 to about 60 minutes; or exposing it to a temperature of about 100° C. to about 175° C. for about 0.5 to about 5 minutes, then about 140° C. to about 200° C. for about 0.5 to about 5 minutes; or exposing it to a temperature of about 100° C. to about 175° C. for about 0.5 to about 5 minutes, then about 140° C. to about 200° C. for about 0.5 to about 5 minutes, and then about 200° C. to about 300° C. for about 1 to about 10 minutes. The coated and baked wafers then undergo CMP using suitable slurry, process, and cleaning parameters to expose the copper pads beneath the dielectric. The wafers are inspected for defects using a KLA Surfscan or similar metrology tool. The CMP'd wafers with sufficiently low defect counts are then bonded together in a commercial wafer bonder under the temperature and pressure conditions described in Section IV of this patent. The bond strength is measured using a Maszara test, double cantilever beam test, shear strength test, or other similar method. The bonded wafers may undergo backgrinding to thin the silicon substrate and then diced into smaller dies. The bond strength of an individual die may be quantified using a die shear bond test.

### Example 23: UV-Exposed Dielectric Film Bonding

In a variation of Example 22, the dielectric films are exposed to ultraviolet radiation during at least one of the bake steps prior to CMP in order to catalyze a higher degree of condensation in the cured film.

### Example 24: Plasma-Treated Dielectric Film Bonding

In a variation of Example 22, the dielectric films are exposed to plasma treatment after CMP and prior to bonding in order to activate surface functional groups that will participate in bonding.

### Example 25: Die-to-Wafer Bonding

In a variation of Example 22, one wafer is diced into smaller dies prior to bonding. In this example, the cured dielectric layer is temporarily bound to a substrate such as silicon or glass using a suitable adhesive. The silicon on the target wafer is then ground down to the desired thickness. Next, the adhesive is removed using a chemical, thermal, or radiation treatment. The target wafer is then cleaned and diced. The individual dies from the first wafer are bonded to the second wafer using a suitable die-to-wafer bonder, and the bond strength is quantified using a die shear bond test.

### Example 26: Die-to-Die Bonding

In a variation of Example 22, both wafers are diced into smaller dies prior to bonding. Each wafer is prepared for dicing following the same process described above. The individual dies are bonded together using a suitable die-to-die bonder, and the bond strength is quantified using a die shear bond test.

### ASPECTS

Aspect 1 is a semiconductor package, comprising: a first semiconductor component and second semiconductor component bonded together with a bonding layer; wherein the bonding layer comprises a siloxane coating of the following formula:

[R_{w}R′ₓR″_{y}SiO_{z}]ₙ

wherein R, R′, and R″ are each an alkyl group, an aryl group, a hydroxyl group, or an alkoxyl group, wherein the alkyl group and/or the aryl group may each independently include one or more polar protic or aprotic functional groups selected from, but not limited to, hydroxyl, amino, or carboxyl functionalities; w is 0-1.5; x is 0-1.5; y is 0-1.5; z is 1.2-2; and n is the number of repeating siloxane monomer units between 10-100,000. Any of R, R′, or R″ may also contain a reactive functional group.

Aspect 2 is the semiconductor package of Aspect 1, wherein each of the first semiconductor component and second semiconductor component are spin-coated with the siloxane coating on a top surface of each of the first semiconductor component and the second semiconductor component; and wherein the bonding layer comprises bonds formed between the siloxane coating on the top surface of the first semiconductor component and the siloxane coating on the top surface of the second semiconductor component at an interface between the top surface of the first semiconductor component and the top surface of the second semiconductor component.

Aspect 3 is the semiconductor package of either Aspect 1 or Aspect 2, wherein the siloxane coating comprises at least one silicon-based compound with a molecular weight (Mw) from 1000 to 1000000 g/mol, as determined by gel permeation chromatography using polystyrene standards.

Aspect 4 is the semiconductor package of any one of Aspects 1-3, wherein the first semiconductor component comprises at least one copper interconnect and the second semiconductor component comprises at least one copper interconnect; and wherein each of the at least one copper interconnect of the first semiconductor component and the at least one copper interconnect of the second semiconductor component is configured to establish an electrical connection between the first semiconductor component and the second semiconductor component.

Aspect 5 is the semiconductor package of any one of Aspects 1-4, wherein the siloxane coating further comprises at least one of: a catalyst; a crosslinker; a surfactant; and one or more additional additives.

Aspect 6 is the semiconductor package of any one of Aspects 1-5, wherein the siloxane coating is derived from a silicon-based compound of at least one of: a siloxane monomer of the following formula:

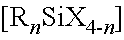

wherein R is an alkyl group, an aryl group, or an alkoxyl group, wherein the alkyl group and/or the aryl group may each independently include one or more polar protic or aprotic functional groups selected from, but not limited to, hydroxyl, amino, or carboxyl functionalities; X is a hydrolysable group selected from an alkoxy group, —OR group, an acetoxy group, or a halogen including Cl, I, Br, or F;
a polysiloxane of the following formula:

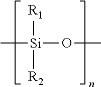

wherein n is at least 3 and less than 10,000; and
a silsesquioxane; and a polysilsesquioxane.

Aspect 7 is the semiconductor package of any one of Aspects 1-6, wherein each of the first semiconductor component and the second semiconductor component comprises one of a wafer, die, chip, or an integrated device.

Aspect 8 is a semiconductor package comprising: a first semiconductor component and second semiconductor component bonded together with a bonding layer; wherein the bonding layer comprises: a first coating composition comprising a siloxane coating of the following formula:

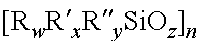

wherein R, R′, and R″ are each an alkyl group, an aryl group, a hydroxyl group, or an alkoxyl group, any of which may additionally contain a reactive functional group, wherein the alkyl group and/or the aryl group may each independently include one or more polar protic or aprotic functional groups selected from, but not limited to, hydroxyl, amino, or carboxyl functionalities; w is 0-1.5; x is 0-1.5; y is 0-1.5; z is 1.2-2; and n is the number of repeating siloxane monomer units between 10-100,000; and a second coating.

Aspect 9 is the semiconductor package of Aspect 8, wherein the second coating is a SiO₂ coating, and wherein the first semiconductor component is spin-coated with the siloxane coating on a top surface of the first semiconductor component and the second semiconductor component is coated with the SiO₂ coating by chemical vapor deposition on a top surface of the second semiconductor component; and wherein the bonding layer comprises bonds formed between the siloxane coating on the top surface of the first semiconductor component and the SiO₂ coating on the top surface of the second semiconductor component at an interface between the top surface of the first semiconductor component and the top surface of the second semiconductor component.

Aspect 10 is the semiconductor package of either Aspect 8 or Aspect 9, wherein the siloxane coating comprises a silicon-based compound with a molecular weight (Mw) from 1000 to 1000000 g/mol, as determined by gel permeation chromatography using polystyrene standards.

Aspect 11 is the semiconductor package of any one of Aspects 8-10, wherein the first semiconductor component comprises at least one copper interconnect and the second semiconductor component comprises at least one copper interconnect; and wherein each of the at least one copper interconnect of the first semiconductor component and the at least one copper interconnect of the second semiconductor component is configured to establish an electrical connection between the first semiconductor component and the second semiconductor component.

Aspect 12 is the semiconductor package of any one of Aspects 8-11, wherein the siloxane coating further comprises at least one of: a catalyst; a crosslinker; a surfactant; and one or more additional additives.

Aspect 13 is the semiconductor package of any one of Aspects 8-12, wherein the siloxane coating is derived from a silicon-based compound of at least one of: a siloxane monomer of the following formula:

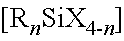

wherein R is an alkyl group, an aryl group, or an alkoxyl group, wherein the alkyl group and/or the aryl group may each independently include one or more polar protic or aprotic functional groups selected from, but not limited to, hydroxyl, amino, or carboxyl functionalities; X is a hydrolysable group selected from an alkoxy group, —OR group, an acetoxy group, or a halogen including Cl, I, Br, or F;
a polysiloxane of the following formula:

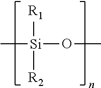

wherein n is at least 3 and less than 50,000; and
a silsesquioxane; and a polysilsesquioxane.

Aspect 14 is the semiconductor package of any one of Aspects 8-13, wherein each of the first semiconductor component and the second semiconductor component comprises one of a wafer, die, chip, or an integrated device.

Aspect 15 is a method of fusing a first semiconductor component and a second semiconductor component to form a device, the method comprising: applying a first coating composition to a top surface of the first semiconductor component to form a first coated semiconductor component; applying a second coating composition to a top surface of the second semiconductor component to form a second coated semiconductor component; wherein at least one of the first coating composition and the second coating composition comprises a siloxane coating composition of the following formula:

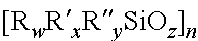

wherein R, R′, and R″ are each an alkyl group, an aryl group, a hydroxyl group, or an alkoxyl group, any of which may additionally contain a reactive functional group, wherein the alkyl group and/or the aryl group may each independently include one or more polar protic or aprotic functional groups selected from, but not limited to, hydroxyl, amino, or carboxyl functionalities; w is 0-1.5; x is 0-1.5; y is 0-1.5; z is 1.2-2; and n is the number of repeating siloxane monomer units between 10-100,000; wherein the siloxane coating composition is applied by spin-coating;
contacting the top surface of the first coated semiconductor component and the top surface of the second coated semiconductor component forming the device; and curing the device in a final cure step at a temperature of 200-450° C. for at least 1 hour.

Aspects 16 is the method of Aspect 15, further comprising pre-curing the siloxane coating composition.

Aspect 17 is the method of Aspect 16, wherein pre-curing comprises at least one of: exposing the siloxane coating composition to a temperature from 40-100° C. for 10-60 seconds; exposing the siloxane coating composition to room temperature (20-25° C.) for 10 to 60 minutes; exposing the siloxane coating composition to a temperature of 100-175° C. for 30 seconds to 5 minutes, then 140-200° C. for 30 seconds to 5 minutes; and exposing the siloxane coating composition to a temperature of 100-175° C. for 30 seconds to 5 minutes, then 140-200° C. for 30 seconds to 5 minutes, and then 200-300° C. for 1-10 minutes.

Aspect 18 is the method of either Aspect 16 or Aspect 17, wherein the siloxane coating composition has a dry film thickness of 7000-10,000 Å after pre-curing.

Aspect 19 is the method of any one of Aspects 15-18, further comprising applying pressure to the device during the final cure step.

Aspect 20 is the method of any one of Aspects 15-19, wherein the first coating composition is the siloxane composition applied by spin-coating and the second coating composition is a SiO₂ coating composition applied by chemical vapor deposition.

Aspect 21 is the method of any one of Aspects 15-20, wherein the siloxane coating composition further comprises at least one of: a solvent; a crosslinker; a catalyst; a surfactant; and one or more additional additives.

Aspect 22 is the method of Aspect 20, wherein the siloxane coating composition comprises: 10-50 wt. % of the at least one silicon-based compound; and 50-90 wt. % of a solvent, based on the total weight of the siloxane coating composition.

Aspect 23 is the method of any one of Aspects 15-22, wherein the siloxane coating composition is derived from a silicon-based compound of at least one of: a siloxane monomer of the following formula:

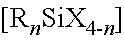

wherein R is an alkyl group, an aryl group, or an alkoxyl group, wherein the alkyl group and/or the aryl group may each independently include one or more polar protic or aprotic functional groups selected from, but not limited to, hydroxyl, amino, or carboxyl functionalities; X is a hydrolysable group selected from an alkoxy group, —OR group, an acetoxy group, or a halogen including Cl, I, Br, or F;
a polysiloxane of the following formula:

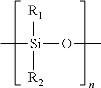

wherein n is at least 3 and less than 10,000; and
a silsesquioxane; and a polysilsesquioxane.

Aspect 24 is the method of any one of Aspects 15-23, wherein each of the first semiconductor component and the second semiconductor component comprises one of a wafer, die, chip, or an integrated device.

What is claimed is:

1. A semiconductor package, comprising:
a first semiconductor component and second semiconductor component bonded together with a bonding layer;
wherein the bonding layer comprises a siloxane coating of the following formula: 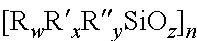
wherein R, R′, and R″ are each an alkyl group, an aryl group, a hydroxyl group, or an alkoxyl group, any of which may additionally contain a reactive functional group, wherein the alkyl group and/or the aryl group may each independently include one or more polar protic or aprotic functional groups selected from, but not limited to, hydroxyl, amino, or carboxyl functionalities;
w is 0-1.5;
x is 0-1.5;
y is 0-1.5;
z is 1.2-2;
and n is the number of repeating siloxane monomer units between 10-100,000.

2. The semiconductor package of claim 1, wherein each of the first semiconductor component and second semiconductor component are spin-coated with the siloxane coating on a top surface of each of the first semiconductor component and the second semiconductor component; and
wherein the bonding layer comprises bonds formed between the siloxane coating on the top surface of the first semiconductor component and the siloxane coating on the top surface of the second semiconductor component at an interface between the top surface of the first semiconductor component and the top surface of the second semiconductor component, optionally wherein the siloxane coating comprises at least one silicon-based compound with a molecular weight (Mw) from 1000 to 1000000 g/mol, as determined by gel permeation chromatography using polystyrene standards.

3. The semiconductor package of claim 1, wherein the first semiconductor component comprises at least one copper interconnect and the second semiconductor component comprises at least one copper interconnect; and
wherein each of the at least one copper interconnect of the first semiconductor component and the at least one copper interconnect of the second semiconductor component is configured to establish an electrical connection between the first semiconductor component and the second semiconductor component.

4. The semiconductor package of claim 1, wherein the siloxane coating further comprises at least one of:
a catalyst;
a crosslinker;
a surfactant; and
one or more additional additives.

5. The semiconductor package of claim 1, wherein the siloxane coating is derived from a silicon-based compound of at least one of:
a siloxane monomer of the following formula: 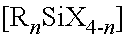
wherein R is an alkyl group, an aryl group, or an alkoxyl group, wherein the alkyl group and/or the aryl group may each independently include one or more polar protic or aprotic functional groups selected from, but not limited to, hydroxyl, amino, or carboxyl functionalities; and
X is a hydrolysable group selected from an alkoxy group, —OR group, an acetoxy group, or a halogen including Cl, I, Br, or F;
a polysiloxane of the following formula: 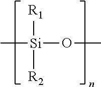
wherein n is at least 3 and less than 10,000;
a silsesquioxane; and
a polysilsesquioxane.

6. The semiconductor package of claim 1, wherein each of the first semiconductor component and the second semiconductor component comprises one of a wafer, die, chip, or an integrated device.

7. A semiconductor package, comprising:
a first semiconductor component and second semiconductor component bonded together with a bonding layer;
wherein the bonding layer comprises:
a first coating comprising a siloxane coating of the following formula: 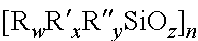
wherein R, R′, and R″ are each an alkyl group, an aryl group, a hydroxyl group, or an alkoxyl group, any of which may additionally contain a reactive functional group;
w is 0-1.5;
x is 0-1.5;
y is 0-1.5;
z is 1.2-2;
and n is the number of repeating siloxane monomer units between 10-100000.

8. The semiconductor package of claim 7, wherein the second coating is a SiO₂ coating; and
wherein the first semiconductor component is spin-coated with the siloxane coating on a top surface of the first semiconductor component and the second semiconductor component is coated with the SiO₂ coating by chemical vapor deposition on a top surface of the second semiconductor component; and
wherein the bonding layer comprises bonds formed between the siloxane coating on the top surface of the first semiconductor component and the SiO₂ coating on the top surface of the second semiconductor component at an interface between the top surface of the first semiconductor component and the top surface of the second semiconductor component, optionally wherein the siloxane coating comprises a silicon-based compound with a molecular weight (Mw) from 1000 to 1000000 g/mol, as determined by gel permeation chromatography using polystyrene standards.

9. The semiconductor package of claim 7, wherein the first semiconductor component comprises at least one copper interconnect and the second semiconductor component comprises at least one copper interconnect; and
wherein each of the at least one copper interconnect of the first semiconductor component and the at least one copper interconnect of the second semiconductor component is configured to establish an electrical connection between the first semiconductor component and the second semiconductor component.

10. The semiconductor package of claim 7, wherein the siloxane coating further comprises at least one of:
a catalyst;
a crosslinker;
a surfactant; and
one or more additional additives.

11. The semiconductor package of claim 7, wherein the siloxane coating is derived from a silicon-based compound of at least one of:
a siloxane monomer of the following formula: 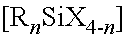
wherein R is an alkyl group, an aryl group, or an alkoxyl group, wherein the alkyl group and/or the aryl group may each independently include one or more polar protic or aprotic functional groups selected from, but not limited to, hydroxyl, amino, or carboxyl functionalities; and
X is a hydrolysable group selected from an alkoxy group, —OR group, an acetoxy group, or a halogen including Cl, I, Br, or F;
a polysiloxane of the following formula: 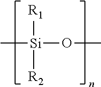
wherein n is at least 3 and less than 50,000;
a silsesquioxane; and
a polysilsesquioxane.

12. The semiconductor package of claim 7, wherein each of the first semiconductor component and the second semiconductor component comprises one of a wafer, die, chip, or an integrated device.

13. A method of fusing a first semiconductor component and a second semiconductor component to form a device, the method comprising:
applying a first coating composition to a top surface of the first semiconductor component to form a first coated semiconductor component;
applying a second coating composition to a top surface of the second semiconductor component to form a second coated semiconductor component;
wherein at least one of the first coating composition and the second coating composition comprises a siloxane coating composition of the following formula: 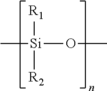
wherein R, R′, and R″ are each an alkyl group, an aryl group, a hydroxyl group, or an alkoxyl group, any of which may additionally contain a reactive functional group, wherein the alkyl group and/or the aryl group may each independently include one or more polar protic or aprotic functional groups selected from, but not limited to, hydroxyl, amino, or carboxyl functionalities;
w is 0-1.5;
x is 0-1.5;
y is 0-1.5;
z is 1.2-2;
and n is the number of repeating siloxane monomer units between 10-100000
wherein the siloxane coating composition is applied by spin-coating;
contacting the top surface of the first coated semiconductor component and the top surface of the second coated semiconductor component forming the device; and
curing the device in a final cure step at a temperature of 200-450° C. for at least 1 hour, optionally further comprising pre-curing the siloxane coating composition.

14. The method of claim 13, wherein pre-curing comprises at least one of:
exposing the siloxane coating composition to a temperature from 40-100° C. for 10-60 seconds;
exposing the siloxane coating composition to room temperature (20-25° C.) for 10 to 60 minutes;
exposing the siloxane coating composition to a temperature of 100-175° C. for 30 seconds to 5 minutes, then 140-200° C. for 30 seconds to 5 minutes; and
exposing the siloxane coating composition to a temperature of 100-175° C. for 30 seconds to 5 minutes, then 140-200° C. for 30 seconds to 5 minutes, and then 200-300° C. for 1-10 minutes, optionally wherein the siloxane coating composition has a dry film thickness of 7000-10,000 Å after pre-curing.

15. The method of claim 13, further comprising applying pressure to the device during the final cure step.

16. The method of claim 13, wherein the first coating composition is the siloxane composition applied by spin-coating and the second coating composition is a SiO₂ coating composition applied by chemical vapor deposition.

17. The method of claim 13, wherein the siloxane coating composition further comprises at least one of:
a solvent;
a crosslinker;
a catalyst;
a surfactant; and
one or more additional additives.

18. The method of claim 17, wherein the siloxane coating composition comprises:
10-50 wt. % of the at least one silicon-based compound; and
50-90 wt. % of a solvent, based on the total weight of the siloxane coating composition.

19. The method of claim 13, wherein the siloxane coating composition is derived from a silicon-based compound of at least one of:
a siloxane monomer of the following formula: 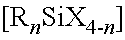
wherein R is an alkyl group, an aryl group, or an alkoxyl group, wherein the alkyl group and/or the aryl group may each independently include one or more polar protic or aprotic functional groups selected from, but not limited to, hydroxyl, amino, or carboxyl functionalities; and
X is a hydrolysable group selected from an alkoxy group, —OR group, an acetoxy group, or a halogen including Cl, I, Br, or F;
a polysiloxane of the following formula: 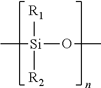
wherein n is at least 3 and less than 10,000;
a silsesquioxane; and
a polysilsesquioxane.

20. The method of claim 13, wherein each of the first semiconductor component and the second semiconductor component comprises one of a wafer, die, chip, or an integrated device.
